(19) United States
(12) Patent Application Publication
(10) Pub. No.: US 2025/0386641 A1
(43) Pub. Date: Dec. 18, 2025

(54) DISPLAY APPARATUS

(71) Applicant: LG Display Co., Ltd., Seoul (KR)

(72) Inventors: Woojin SEONG, Paju-si (KR); DongHyun CHUNG, Seoul (KR); Wonsub SO, Goyang-si (KR); Hyoungsun PARK, Seoul (KR); YoungHyun SON, Goyang-si (KR)

(73) Assignee: LG Display Co., Ltd., Seoul (KR)

(21) Appl. No.: 19/236,497

(22) Filed: Jun. 12, 2025

(30) Foreign Application Priority Data
Jun. 13, 2024 (KR) 10-2024-0077235
Jul. 22, 2024 (KR) 10-2024-0096698

(51) Int. Cl. H10H 29/49; H01L 25/16; H10H 29/41

(52) U.S. Cl. CPC H10H 29/49; H01L 25/167; H10H 29/41

(57) ABSTRACT

A display apparatus may include a substrate; a display area; a non-display area outside the display area; a groove disposed in the display area; an inorganic insulating layer disposed in an area excluding the groove in the display area; a pixel driving circuit disposed in the groove; and a plurality of micro-LEDs disposed on the pixel driving circuit and electrically connected to the pixel driving circuit. Therefore, a transfer rate of the micro-LED may be improved by securing flatness of an area where the pixel driving circuit is disposed above the substrate and an area surrounding the area in the display area.

### CROSS-REFERENCE TO RELATED APPLICATIONS

This application claims the benefit of and priority to Korean Patent Application No. 10-2024-0077235 filed on Jun. 13, 2024 and Korean Patent Application No. 10-2024-0096698 filed on Jul. 22, 2024, in the Korean Intellectual Property Office, the entire contents of each of which are incorporated herein by reference for all purposes.

### BACKGROUND

### 1. Technical Field

The present disclosure relates to a display apparatus.

### 2. Description of Related Art

A display apparatus is applied to various electronic apparatuses such as TV, mobile phones, laptops, and tablets.

The display apparatus includes an organic light emitting display (OLED) apparatus that emits light by itself, a liquid crystal display (LCD) apparatus that requires a separate light source, etc.

Recently, the display apparatus including a light emitting diode (LED) is attracting attention as a next-generation display apparatus. Since the light emitting diode is made of an inorganic material rather than an organic material, the light emitting diode may have a fast-lighting speed and excellent light emitting efficiency, and may display a high brightness image, compared to the liquid crystal display apparatus or the organic light emitting display apparatus.

The description of related art should not be considered prior art merely because it is mentioned in or associated with this section. The description of related art includes information that describes one or more aspects of the subject technology, and the description in this section does not limit the scope of the invention.

### SUMMARY

An aspect of the present disclosure is to provide a display apparatus in which thinning is implemented.

Another aspect of the present disclosure is to provide a display apparatus that can minimize or reduce the problem of reducing flatness of a display area due to the organic insulating materials disposed in a display area flowing into a bending area by alleviating a step between the display area and the bending area.

Another aspect of the present disclosure is to provide a display apparatus in which a transfer rate of a micro-LED is improved by securing flatness of an area where a pixel driving circuit is disposed and an area surrounding the area in a display area.

Another aspect of the present disclosure is to provide a display apparatus in which process optimization is implemented by omitting an additional process for securing flatness of a display area, and in which a manufacturing process and cost are reduced.

Another aspect of the present disclosure is to provide a display apparatus with reduced defects due to foreign materials.

Another aspect of the present disclosure is to provide a display apparatus that can be driven with low power in terms of production energy reduction by blocking air bubbles around a pixel driving circuit to minimize or reduce potential defects and improve lifespan of the display apparatus.

Aspects of the present disclosure are not limited to the above-mentioned aspects, and other aspects, which are not mentioned above, can be clearly understood by those skilled in the art from the following descriptions.

A display apparatus according to an example embodiment of the present disclosure may include a substrate; a display area; a non-display area outside the display area; a groove disposed in the display area; an inorganic insulating layer disposed in an area excluding the groove in the display area; a pixel driving circuit disposed in the groove; and a plurality of micro-LEDs disposed on the pixel driving circuit and electrically connected to the pixel driving circuit. Therefore, a transfer rate of the micro-LED may be improved by securing flatness of an area where the pixel driving circuit is disposed above the substrate and an area surrounding the area in the display area.

A display apparatus according to another example embodiment of the present disclosure may include a substrate; a plurality of grooves disposed on the substrate; a plurality of pixel driving circuits disposed in each of the plurality of grooves on the substrate; a plurality of inorganic insulating layers disposed to surround the plurality of pixel driving circuits while being spaced apart from the plurality of pixel driving circuits on the substrate; an organic insulating layer on the plurality of inorganic insulating layers and the plurality of pixel driving circuits; and a plurality of micro-LEDs disposed on the organic insulating layer and electrically connected to the plurality of pixel driving circuits.

Other detailed matters of the example embodiments are included in the detailed description and the drawings.

According to an example embodiment of the present disclosure, by forming a groove in a substrate and mounting a pixel driving circuit in the groove, a component for flattening an area where the pixel driving circuit is disposed and an area surrounding the area can be omitted, thereby implementing the thinning of the display apparatus.

According to an example embodiment of the present disclosure, by omitting an additional process for flattening the area where the pixel driving circuit is disposed and the area surrounding the area, it is possible to implement the process optimization and reduce the process cost and time.

According to an example embodiment of the present disclosure, by omitting the component for flattening the display area where the pixel driving circuit is disposed, a step between a bending area and the display area can be minimized or reduced, thereby minimizing or reducing the problem of reducing flatness of the display area due to the organic insulating materials disposed in the display area flowing into the bending area.

According to an example embodiment of the present disclosure, by securing flatness of an upper portion of the substrate in the display area, it is possible to enhance a transfer rate of a micro-LED.

According to an example embodiment of the present disclosure, by disposing a passivation layer made of the organic insulating material to fill the gap between the pixel driving circuit and the groove, air bubbles around the pixel driving circuit may be removed to minimize or reduce potential defects and improve the lifespan of the display apparatus, thereby enabling low-power operation of the display apparatus in terms of production energy reduction.

According to an example embodiment of the present disclosure, by disposing an adhesive pattern only in the groove of the substrate on which the pixel driving circuit is disposed, it is possible to minimize or reduce defects due to unnecessary foreign materials being attached to the adhesive pattern.

The effects according to the present disclosure are not limited to the contents exemplified above, and more various effects are included in the present specification.

Additional features, advantages, and aspects of the present disclosure are set forth in part in the description that follows and in part will become apparent from the present disclosure or may be learned by practice of the inventive concepts provided herein. Other features, advantages, and aspects of the present disclosure may be realized and attained by the descriptions provided in the present disclosure, or derivable therefrom, and the claims hereof as well as the drawings. It is intended that all such features, advantages, and aspects be included within this description, be within the scope of the present disclosure, and be protected by the following claims. Nothing in this section should be taken as a limitation on those claims. Further aspects and advantages are discussed below in conjunction with embodiments of the present disclosure.

It is to be understood that both the foregoing description and the following description of the present disclosure are examples, and are intended to provide further explanation of the disclosure as claimed.

### BRIEF DESCRIPTION OF DRAWINGS

The accompanying drawings, which are included to provide a further understanding of the present disclosure, are incorporated in and constitute a part of this present disclosure, illustrate aspects and embodiments of the present disclosure, and together with the description serve to explain principles and examples of the disclosure. In the drawings:

FIG. 1 is an exploded perspective view of a display apparatus according to an example embodiment of the present disclosure;

FIG. 2 is a plan view of the display apparatus according to an example embodiment of the present disclosure;

FIG. 3 is an enlarged view of the display apparatus according to an example embodiment of the present disclosure;

FIG. 4 is a diagram illustrating a circuit structure according to an example embodiment of the present disclosure;

FIG. 5 is a plan view of the display apparatus according to an example embodiment of the present disclosure;

FIG. 6 is a plan view of the display apparatus according to an example embodiment of the present disclosure;

FIG. 7 is a plan view of the display apparatus according to an example embodiment of the present disclosure;

FIG. 8 is a cross-sectional view taken along line VIII-VIII′ of FIG. 3;

FIG. 9 is a cross-sectional view of the display apparatus according to an example embodiment of the present disclosure;

FIGS. 10A to 10C are process diagrams of a method for manufacturing a display apparatus according to an example embodiment of the present disclosure; and

FIGS. 11 to 14 are diagrams illustrating apparatuses to which the display apparatus according to example embodiments of the present disclosure is applied.

Throughout the drawings and the detailed description, unless otherwise described, the same drawing reference numerals should be understood to refer to the same elements, features, and structures. The sizes, lengths, and thicknesses of layers, regions and elements, and depiction thereof may be exaggerated for clarity, illustration, and/or convenience.

### DETAILED DESCRIPTION

Advantages and characteristics of the present disclosure and a method of achieving the advantages and characteristics will be clear by referring to example embodiments described below in detail together with the accompanying drawings. However, the present disclosure is not limited to the example embodiments disclosed herein but will be implemented in various forms. The example embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the example embodiments of the present disclosure are merely examples, and the present disclosure is not limited thereto. Like reference numerals generally denote like elements throughout the specification. Further, in the following description of the present disclosure, a detailed explanation of known related technologies may be omitted to avoid unnecessarily obscuring the subject matter of the present disclosure. The terms such as “including”, “having”, and “comprising” used herein are generally intended to allow other components to be added unless the terms are used with the term “only”. Any references to singular may include plural unless expressly stated otherwise. For example, an element may be one or more elements. An element may include a plurality of elements. The word “exemplary” is used to mean serving as an example or illustration. Embodiments are example embodiments. Aspects are example aspects. In one or more implementations, “embodiments,” “examples,” “aspects,” and the like should not be construed to be preferred or advantageous over other implementations. An embodiment, an example, an example embodiment, an aspect, or the like may refer to one or more embodiments, one or more examples, one or more example embodiments, one or more aspects, or the like, unless stated otherwise. Further, the term “may” encompasses all the meanings of the term “can.”

Components are interpreted to include an ordinary error range even if not expressly stated.

When the position relation between two parts is described using the terms such as “on”, “above”, “below”, and “next”, one or more parts may be positioned between the two parts unless the terms are used with the term “immediately” or “directly”.

When the relation of a time sequential order is described using the terms such as “after”, “continuously to”, “next to”, and “before”, the order may not be continuous unless the terms are used with the term “immediately” or “directly”.

Although the terms first, second, or the like are used to describe various components, these components are not limited by these terms. These terms are only used to distinguish one component from another. Thus, a first component referred to below may also be a second component within the technical scope of the present disclosure.

In describing components of the present disclosure, terms such as first, second, A, B, (a), or (b) may be used. These terms are only intended to distinguish the component from other components, and the nature, order, sequence, or number of the components are not limited by the terms.

When a component is described as being “connected”, “coupled”, “joined”, or “attached” to another component, it should be understood that that the component can be directly connected, coupled, joined, or attached to that other component, but that other components may also be interposed between the components which can be indirectly connected, coupled, joined, or attached, unless otherwise expressly stated.

When a component or layer is described as “overlapping” another component or layer, it should be understood that the component or layer may directly contact or overlap the other component or layer, but that other components may also be interposed between the components that may indirectly overlap each other, unless specifically stated otherwise.

“At least one” should be understood to include any combination of one or more of the associated components. For example, “at least one of the first, second, and third components” could be understood to include any combination of two or more of the first, second, and third components, as well as the first, second, or third components.

A “first direction”, “second direction”, “third direction”, “X-axis direction”, “Y-axis direction” and “Z-axis direction” should not be interpreted as merely geometric relationships in which the relationship between them is perpendicular to each other, but may mean a broader directionality within the scope in which the configuration of the present disclosure can function functionally.

The features of various embodiments of the present disclosure can be partially or entirely adhered to or combined with each other and can be interlocked and operated in technically various ways, and the embodiments can be carried out independently of or in association with each other.

Hereinafter, a display apparatus according to example embodiments of the present disclosure will be described in detail with reference to accompanying drawings.

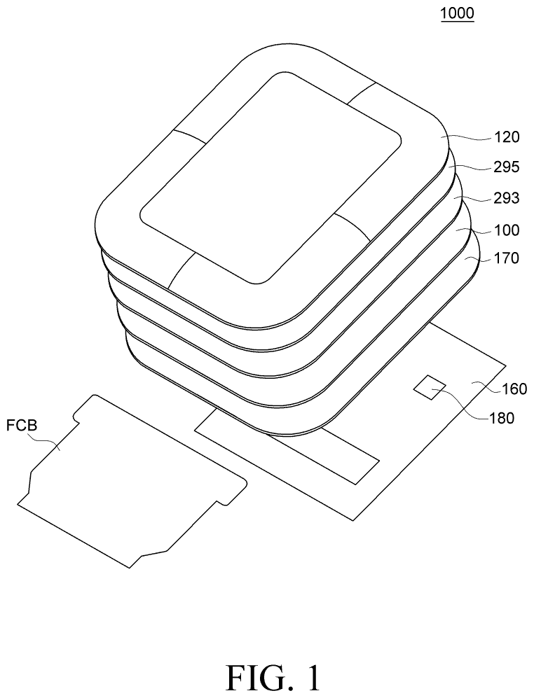

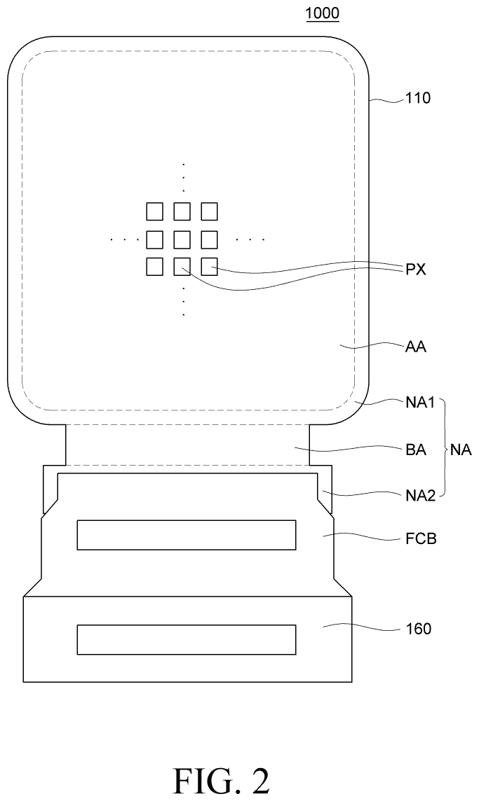

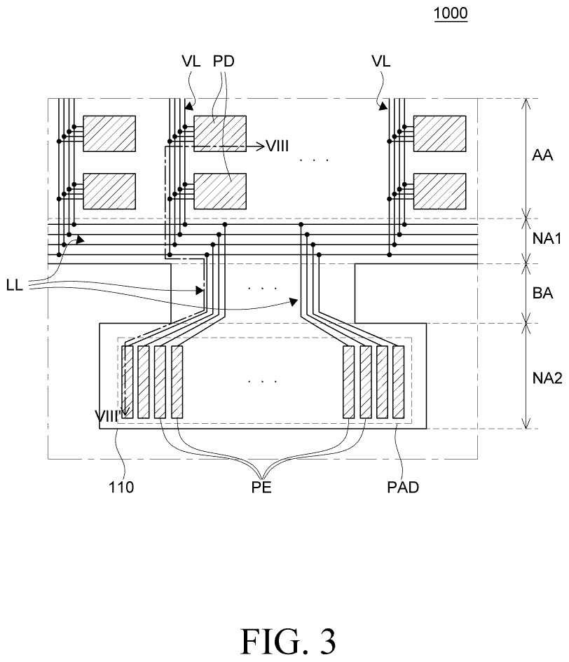

FIG. 1 is a perspective view of a display apparatus according to an example embodiment of the present disclosure. FIG. 2 is a plan view of the display apparatus according to an example embodiment of the present disclosure. FIG. 3 is an enlarged view of the display apparatus according to an example embodiment of the present disclosure.

Referring to FIGS. 1 to 3, a display apparatus 1000 according to an example embodiment of the present disclosure may include a display panel 100, a polarizing layer 293, an adhesive layer 295, a cover member 120, a support substrate 170, a flexible circuit board FCB, and a printed circuit board 160.

For example, the display panel 100 of the display apparatus 1000 may include a substrate 110. The substrate 110 may be a member that supports other components of the display apparatus 1000. The substrate 110 may be made of an insulating material. For example, the substrate 110 may be made of glass, resin, or the like. In addition, the substrate 110 may be made of a material having flexibility. For example, the substrate 110 may be made of organic insulating materials, which are plastic materials having flexibility, such as polyimide (PI). However, the example embodiments of the present disclosure are not limited thereto.

The display panel 100 may implement information, videos, and/or images provided to a user. For example, the display panel 100 may include a display area AA and a non-display area NA surrounding the display area AA. For example, the substrate 110 may include the display area AA and the non-display area NA. The display area AA and the non-display area NA are not limited to the substrate 110 but may be described throughout the display apparatus 1000.

The display area AA may be an area where images are displayed. The display area AA may include a plurality of pixels PX. Each of the plurality of pixels PX may be composed of a plurality of sub-pixels. A plurality of micro-LEDs may be disposed in each of the plurality of sub-pixels.

The non-display area NA may be an area where images are not displayed. Various wirings and circuits for driving the plurality of pixels PX of the display area AA may be disposed in the non-display area NA. For example, various wirings and driving circuits may be mounted in the non-display area NA, and a pad part PAD to which an integrated circuit, a printed circuit, etc., are connected may be disposed, but the example embodiments of the present disclosure are not limited thereto.

For example, the driving circuit may be a data driving circuit and/or a gate driving circuit, but the example embodiments of the present disclosure are not limited thereto. Wirings to which control signals for controlling the driving circuits are supplied may be disposed. For example, the control signal may include various timing signals that include a clock signal, an input data enable signal, and synchronization signals, but the example embodiments of the present disclosure are not limited thereto. The control signal may be received through the pad part PAD. For example, link wirings LL for transmitting signals may be disposed in the non-display area NA. For example, driving components such as a flexible circuit board FCB and a printed circuit board 160 may be connected to the pad part PAD.

According to the present disclosure, the non-display area NA may include a first non-display area NA1, a bending area BA, and a second non-display area NA2. For example, the first non-display area NA1 may be an area surrounding at least a portion of the display area AA. The bending area BA is an area extending from at least one side of a plurality of sides of the first non-display area NA1 and may be a bendable area. The second non-display area NA2 is an area extending from the bending area BA, and may have the pad part PAD disposed therein. For example, the bending area BA may be in a bent state, and the remaining area of the substrate 110 excluding the bending area BA may be in a flat state. In this case, as the bending area BA is bent, the second non-display area NA2 may be located on a rear surface of the display area AA. However, the example embodiments of the present disclosure are not limited thereto.

The display area AA of the substrate 110 or the display apparatus 1000 may be configured in various shapes according to the design of the display apparatus 1000. For example, the display area AA may be configured in a rectangular shape having four corners formed in a round shape, but the example embodiments of the present disclosure are not limited thereto. For another example, the display area AA may be configured in a rectangular shape having four corners formed in a right-angle shape, a circular shape, etc., but the example embodiments of the present disclosure are not limited thereto.

According to the present disclosure, a width of the second non-display area NA2 where a plurality of pad electrodes PE is disposed may be wider than that of the bending area BA where only the plurality of link wirings LL is disposed. In addition, a width of the display area AA where the plurality of sub-pixels is disposed may be wider than that of the bending area BA where only the plurality of link wirings LL is disposed. In the drawing, the width of the bending area BA is illustrated as being narrower than widths of other areas of the substrate 110, but the shape of the substrate 110 including the bending area BA is example, and the example embodiments of the present disclosure are not limited thereto.

Referring to FIG. 3, a plurality of pixel driving circuits PD may be disposed in the display area AA. The plurality of pixel driving circuits PD may be circuits for driving micro-LEDs of the plurality of sub-pixels. Each of the plurality of pixel driving circuits PD includes a plurality of transistors including a driving transistor, a storage capacitor, etc., and may control a light-emitting operation of a plurality of micro-LEDs by supplying a control signal, power, and a driving current to the micro-LEDs of the plurality of sub-pixels. For example, the pixel driving circuit PD may include a power wiring and a signal wiring for controlling a light-emitting on/off and/or light-emitting time of the micro-LED. For example, the plurality of pixel driving circuits PD may be driving drivers manufactured using a metal-oxide-semiconductor field effect transistor (MOSFET) manufacturing process on a semiconductor substrate, but the example embodiments of the present disclosure are not limited thereto. The driving driver includes the plurality of pixel driving circuits PD and may drive the plurality of sub-pixels.

Referring to FIG. 1 together, the flexible circuit board FCB and the printed circuit board 160 may be disposed under the display panel 100. The flexible circuit board FCB and the printed circuit board 160 may be disposed at least on one edge of the display panel 100, but the example embodiments of the present disclosure are not limited thereto. One side of the flexible circuit board FCB may be attached to the display panel 100, and the other side may be attached to the printed circuit board 160, but the example embodiments of the present disclosure are not limited thereto. The flexible circuit board FCB may be a flexible film, but the example embodiments of the present disclosure are not limited thereto.

The pad part PAD including the plurality of pad electrodes PE may be disposed in the second non-display area NA2. A driving component including one or more flexible circuit boards (or flexible films) FCB and the printed circuit board 160 may be attached or bonded to the pad part PAD. The plurality of pad electrodes PE of the pad part PAD is electrically connected to one or more flexible circuit boards (or flexible films) FCB, and may transmit various signals (or power) from the printed circuit board 160 and the flexible circuit board (or flexible film) FCB to the plurality of pixel driving circuits PD of the display area AA.

The flexible circuit board (or flexible film) FCB may be a film in which various components are disposed on a flexible base film. For example, a driving IC such as a gate driver IC or a data driver IC may be disposed on the flexible circuit board (or flexible film) FCB, but the example embodiments of the present disclosure are not limited thereto. The driving IC may be a component that processes data and driving signals for displaying an image. The driving IC may be disposed in a manner such as a chip on glass (COG), a chip on film (COF), or a tape carrier package (TCP) depending on the mounting method, but the example embodiments of the present disclosure are not limited thereto. The flexible circuit board (or flexible film) FCB may be attached or bonded to the plurality of pad electrodes PE through a conductive adhesive layer, but the example embodiments of the present disclosure are not limited thereto.

The printed circuit board 160 may be electrically connected to one or more flexible circuit boards (or flexible films) FCB and may be a component that supplies signals to the driving IC. The printed circuit board 160 may be disposed on one side of the flexible circuit board (or flexible film) FCB and may be electrically connected to the flexible circuit board (or flexible film) FCB. Various components for supplying various signals to the driving IC may be disposed on the printed circuit board 160. For example, various components such as a timing controller, a power supply, a memory, or a processor may be disposed on the printed circuit board 160. For example, the printed circuit board 160 may include a power management integrated circuit (PMIC), but the example embodiments of the present disclosure are not limited thereto.

The printed circuit board 160 may include at least one hole 180, but the example embodiments of the present disclosure are not limited thereto. An internal component that detects ambient light, temperature, etc., that may be provided to a plurality of sensors may be disposed in an area corresponding to at least one hole 180. For example, the internal component may include an ambient light sensor (ALS), a temperature sensor, etc., but the example embodiments of the present disclosure are not limited thereto. For example, the hole 180 may be a transparent hole, but the example embodiments of the present disclosure are not limited thereto.

Referring to FIG. 1, a polarizing layer 293 may be disposed on the display panel 100. The polarizing layer 293 may suppress or reduce light generated from an external light source from entering the display panel 100 and affecting the micro-LEDs, etc.

The cover member 120 may be disposed on the polarizing layer 293. The cover member 120 may be a member for protecting the display panel 100. The adhesive layer 295 may be disposed between the polarizing layer 293 and the cover member 120. The cover member 120 may be attached to the display panel 100 using the adhesive layer 295. The adhesive layer 295 may include an optically clear adhesive (OCA), an optically clear resin (OCR), a pressure sensitive adhesive (PSA), etc., but the example embodiments of the present disclosure are not limited thereto.

A support substrate 170 may be disposed between the display panel 100 and the printed circuit board 160. The support substrate 170 may reinforce the rigidity of the display panel 100. The support substrate 170 may be a back plate, but the example embodiments of the present disclosure are not limited thereto.

Referring to FIGS. 1 to 3, the plurality of link wirings LL may be disposed on the non-display area NA. The plurality of link wirings LL may be wirings that transmit various signals from one or more flexible circuit boards (or flexible films) FCB and the printed circuit board 160 to the display area AA. The plurality of link wirings LL may extend from the plurality of pad electrodes PE of the second non-display area NA2 toward the bending area BA and the first non-display area NA1, and may be electrically connected to a plurality of driving wirings VL of the display area AA. The plurality of pixel driving circuits PD may be driven by receiving signals from one or more flexible circuit boards (or flexible films) FCB and the printed circuit board 160 through the driving wirings VL of the display area AA and the link wirings LL of the non-display area NA.

For example, the plurality of driving wirings VL may be wirings for transmitting signals output from the flexible circuit board (or flexible film) FCB and the printed circuit board 160 to the plurality of pixel driving circuits PD together with the plurality of link wirings LL. The plurality of driving wirings VL may be disposed in the display area AA and electrically connected to each of the plurality of pixel driving circuits PD. The plurality of driving wirings VL may extend from the display area AA toward the non-display area NA and may be electrically connected to the plurality of link wirings LL, respectively. Accordingly, the signals output from the flexible circuit board (or flexible film) FCB and the printed circuit board 160 may be transmitted to each of the plurality of pixel driving circuits PD through the plurality of link wirings LL and the plurality of driving wirings VL.

As the bending area BA is bent, some of the plurality of link wirings LL may be bent together. Stress is concentrated on some of the bent link wirings LL, and thus cracks may occur in the link wirings LL. Accordingly, the plurality of link wirings LL may be made of a conductive material having excellent flexibility to reduce cracks when the bending area BA is bent. For example, the plurality of link wirings LL may be made of a conductive material having excellent flexibility, such as gold (Au), silver (Ag), and aluminum (Al), but the example embodiments of the present disclosure are not limited thereto. In addition, the plurality of link wirings LL may be made of one of various conductive materials used in the display area AA. For example, the plurality of link wirings LL may be made of molybdenum (Mo), chromium (Cr), titanium (Ti), nickel (Ni), neodymium (Nd), copper (Cu), and an alloy of silver (Ag) and magnesium (Mg), or an alloy thereof, but the example embodiments of the present disclosure are not limited thereto. The plurality of link wirings LL may be composed of a multilayer structure including various conductive materials. For example, the plurality of link wirings LL may be composed of a triple-layer structure of titanium (Ti)/aluminum (Al)/titanium (Ti), but the example embodiments of the present disclosure are not limited thereto.

The plurality of link wirings LL may be configured in various shapes to reduce the stress. At least some of the plurality of link wirings LL disposed on the bending area BA may extend in the same direction as an extension direction of the bending area BA, or may extend in a direction different from the extension direction of the bending area BA, thereby reducing the stress. For example, when the bending area BA extends in one direction from the first non-display area NA1 toward the second non-display area NA2, at least some of the link wirings LL disposed on the bending area BA may extend in a direction oblique to the one direction. For another example, at least some of the plurality of link wirings LL may be configured as patterns of various shapes. For example, at least some of the plurality of link wirings LL disposed on the bending area BA may have a shape in which conductive patterns having at least one of a diamond shape, a rhombus shape, a trapezoidal wave shape, a triangular wave shape, a sawtooth wave shape, a sine wave shape, a circular shape, and an omega (Ω) shape are repeatedly disposed, but the example embodiments of the present disclosure are not limited thereto. Therefore, in order to minimize or reduce the stress concentrated on the plurality of link wirings LL and the resulting cracks, the shape of the plurality of link wirings LL may be formed in various shapes including the above-described shapes, but the example embodiments of the present disclosure are not limited thereto.

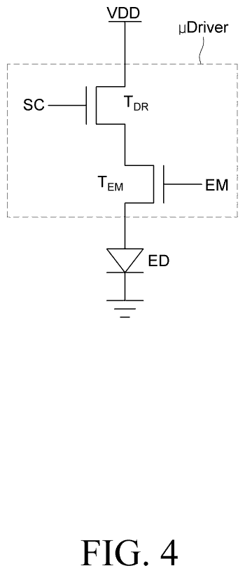

FIG. 4 is a diagram illustrating a circuit structure according to an example embodiment of the present disclosure.

The pixel driving circuit PD may include a micro driver μDriver. The micro-LED ED may be electrically connected to the micro driver μDriver of the pixel driving circuit PD and driven. FIG. 4 illustrates that one micro-LED ED is connected to the micro driver μDriver, but the present disclosure is not limited thereto. For example, eight micro-LEDs ED may be connected to one micro driver μDriver. For another example, 16 micro-LEDs ED may be connected to one micro driver μDriver, or 32 micro-LEDs ED or 64 the micro-LEDs ED may be simultaneously connected to one micro driver μDriver.

One micro driver μDriver may include a driving transistor T_{DR} and a light-emitting transistor T_{EM}, but the example embodiments of the present disclosure are not limited thereto.

For example, a high-potential power supply voltage VDD may be applied to a first electrode of the driving transistor T_{DR}, a first electrode of the light-emitting transistor T_{EM} may be connected to a second electrode of the driving transistor T_{DR}, and a scan signal SC may be applied to a gate electrode of the driving transistor T_{DR}. The scan signal SC applied to the gate electrode of the driving transistor T_{DR} is a direct current (DC) power supply, and a fixed reference voltage may be applied for each frame, but the example embodiments of the present disclosure are not limited thereto.

The second electrode of the driving transistor T_{DR} may be connected to the first electrode of the light-emitting transistor T_{EM}, the micro-LED ED may be connected to the second electrode of the light-emitting transistor T_{EM}, and an emission signal EM may be applied to the gate electrode of the light-emitting transistor T_{EM}. The emission signal EM applied to the gate electrode of the light-emitting transistor T_{EM} may be a pulse width modulation (PWM) signal that varies for each frame, but the example embodiments of the present disclosure are not limited thereto.

A first electrode of the micro-LED ED may be connected to the second electrode of the light-emitting transistor T_{EM}, and a second electrode of the micro-LED ED may be connected to ground. For example, the first electrode may be an anode electrode and the second electrode may be a cathode electrode, but the example embodiments of the present disclosure are not limited thereto.

The driving transistor T_{DR} and the light-emitting transistor T_{EM} may each be an n-type transistor or a p-type transistor.

The driving transistor T_{DR} may be turned on by the scan signal SC applied to the micro driver μDriver from a timing controller, and the light-emitting transistor T_{EM} may be turned on by the emission signal EM. Accordingly, a driving current is applied to the micro-LED ED through the driving transistor T_{DR} and the light-emitting transistor T_{EM} by the high-potential power supply voltage VDD applied to the first electrode of the driving transistor T_{DR}, so the micro-LED ED may emit light.

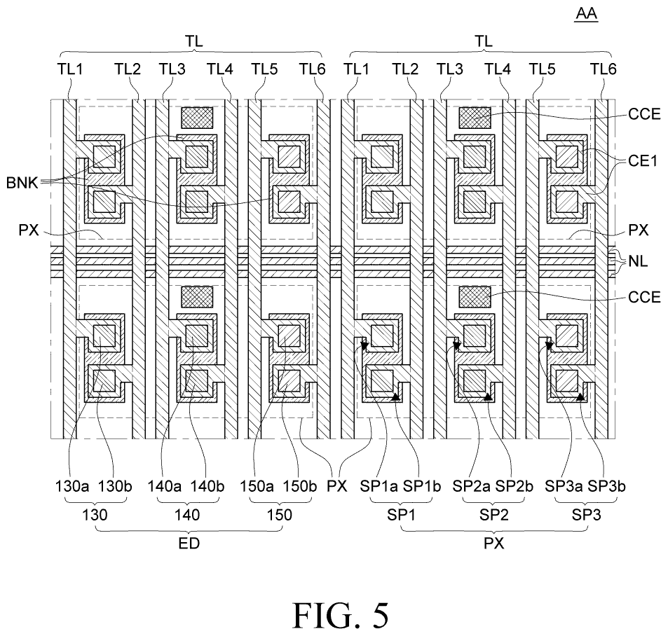

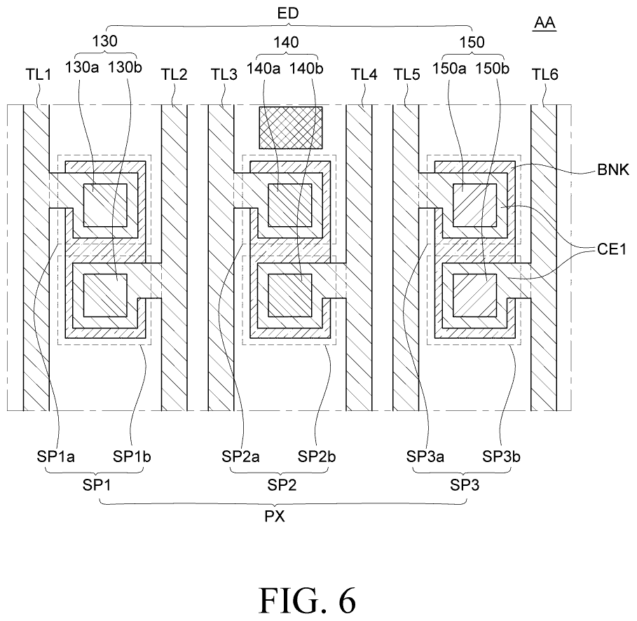

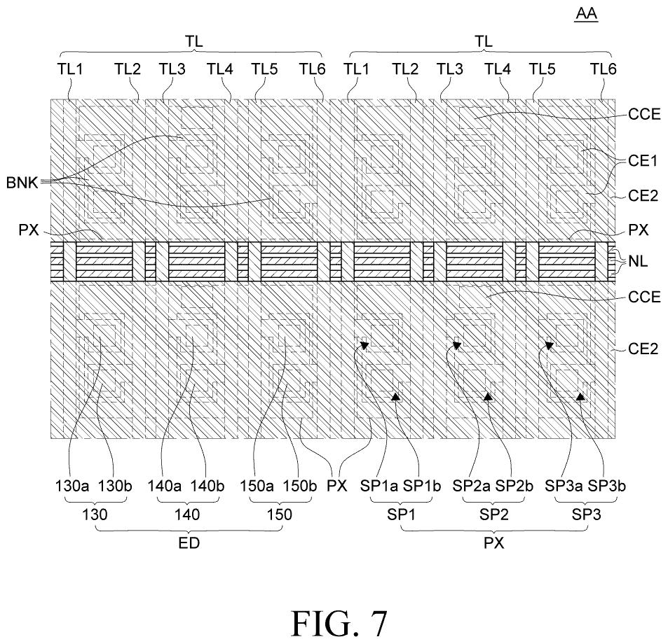

FIGS. 5 to 7 are plan views of the display apparatus according to an example embodiment of the present disclosure. For example, FIG. 5 is an enlarged plan view of the display area including the plurality of pixels. For example, FIG. 6 is an enlarged plan view of the display area including one pixel. For example, FIG. 7 is an enlarged plan view of the display area including the plurality of pixels. In FIGS. 5 and 6, only a plurality of signal wirings TL, a plurality of communication wirings NL, a plurality of first electrodes CE1, a plurality of banks BNK, and a plurality of micro-LEDs ED are illustrated, but the example embodiments of the present disclosure are not limited thereto. FIG. 7 is an enlarged plan view of FIG. 5 in which a plurality of second electrodes CE2 are additionally disposed.

Referring to FIGS. 5 and 6, a plurality of pixels PX composed of a plurality of sub-pixels may be disposed in the display area AA. Each of the plurality of sub-pixels includes a micro-LED ED and may independently emit light. The plurality of sub-pixels may be disposed in a matrix form, forming a plurality of rows and a plurality of columns, but the example embodiments of the present disclosure are not limited thereto.

The plurality of sub-pixels may include a first sub-pixel SP1, a second sub-pixel SP2, and a third sub-pixel SP3. For example, any one of the first sub-pixel SP1, the second sub-pixel SP2, and the third sub-pixel SP3 may be a red sub-pixel, the other may be a green sub-pixel, and the rest may be a blue sub-pixel. A type of the plurality of sub-pixels is example, and the example embodiments of the present disclosure are not limited thereto.

Each of the plurality of pixels PX may include one or more first sub-pixels SP1, one or more second sub-pixels SP2, and one or more third sub-pixels SP3. For example, one pixel PX may include a pair of first sub-pixels SP1, a pair of second sub-pixels SP2, and a pair of third sub-pixels SP3. A pair of first sub-pixels SP1 may be composed of a 1-1st sub-pixel SP1a and a 1-2nd sub-pixel SP1b. A pair of second sub-pixels SP2 may be composed of a 2-1st sub-pixel SP2a and a 2-2nd sub-pixel SP2b. A pair of third sub-pixels SP3 may be composed of a 3-1st sub-pixel SP3a and a 3-2nd sub-pixel SP3b. For example, one pixel PX may include the 1-1st sub-pixel SP1a and the 1-2nd sub-pixel SP1b, the 2-1st sub-pixel SP2a and the 2-2nd sub-pixel SP2b, and the 3-1st sub-pixel SP3a and the 3-2nd sub-pixel SP3b, but the example embodiments of the present disclosure are not limited thereto.

A plurality of sub-pixels forming one pixel PX may be arranged in various ways. For example, in one pixel PX, a pair of first sub-pixels SP1 may be disposed in the same column, a pair of second sub-pixels SP2 may be disposed in the same column, and a pair of third sub-pixels SP3 may be disposed in the same column. The first sub-pixel SP1, the second sub-pixel SP2, and the third sub-pixel SP3 may be disposed in the same row. The number and arrangement of sub-pixels constituting one pixel PX is an example, and the example embodiments of the present disclosure are not limited thereto.

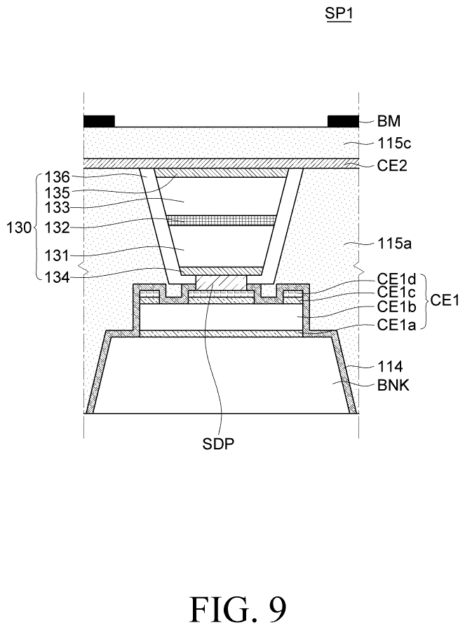

The plurality of signal wirings TL may be disposed in an area between the plurality of sub-pixels. The plurality of signal wirings TL may extend in a column direction between the plurality of sub-pixels. The plurality of signal wirings TL may be wirings that transmit an anode voltage from the pixel driving circuit PD to the plurality of sub-pixels. For example, the plurality of signal wirings TL may be electrically connected to the plurality of pixel driving circuits PD and the first electrodes CE1 of the plurality of sub-pixels. The anode voltage output from a pixel driving circuit PD may be transmitted to the first electrode CE1 of the plurality of sub-pixels through the plurality of signal wirings TL. For example, the first electrode CE1 may be an electrode electrically connected to an anode electrode 134 (see FIG. 9) of the micro-LED ED. Accordingly, the anode voltage from the signal wiring TL may be transmitted to the anode electrode 134 of the micro-LED ED through the first electrode CE1.

Therefore, instead of forming a plurality of transistors and storage capacitors in each of the plurality of sub-pixels, the structure of the display apparatus 1000 may be simplified by using the pixel driving circuit PD in which the plurality of pixel circuits is integrated. In addition, as the circuits disposed in each of the plurality of sub-pixels are integrated in one pixel driving circuit PD, high-efficiency and low-power driving may be possible.

The plurality of signal wirings TL may include a first signal wiring TL1, a second signal wiring TL2, a third signal wiring TL3, a fourth signal wiring TL4, a fifth signal wiring TL5, and a sixth signal wiring TL6. Each of the first signal wiring TL1 and the second signal wiring TL2 may be electrically connected to each of the pair of first sub-pixels SP1. Each of the third signal wiring TL3 and the fourth signal wiring TL4 may be electrically connected to each of the pair of second sub-pixels SP2. Each of the fifth signal wiring TL5 and the sixth signal wiring TL6 may be electrically connected to each of the pair of third sub-pixels SP3.

The first signal wiring TL1 may be disposed on one side of the pair of first sub-pixels SP1, and the second signal wiring TL2 may be disposed on the other side of the pair of first sub-pixels SP1. The first signal wiring TL1 may be electrically connected to the first electrode CE1 of any one of the pair of first sub-pixels SP1, for example, the 1-1st sub-pixel SP1a. The second signal wiring TL2 may be electrically connected to the first electrode CE1 of the remaining of the pair of first sub-pixels SP1, for example, the 1-2nd sub-pixel SP1b.

The third signal wiring TL3 may be disposed on one side of the pair of second sub-pixels SP2, and the fourth signal wiring TL4 may be disposed on the other side of the pair of second sub-pixels SP2. For example, the third signal wiring TL3 may be disposed adjacent to the second signal wiring TL2. The third signal wiring TL3 may be electrically connected to the first electrode CE1 of one of the pair of second sub-pixels SP2, for example, the 2-1st sub-pixel SP2a. The fourth signal wiring TL4 may be electrically connected to the first electrode CE1 of the remaining of the pair of second sub-pixels SP2, for example, the 2-2nd sub-pixel SP2b.

The fifth signal wiring TL5 may be disposed on one side of the pair of third sub-pixels SP3, and the sixth signal wiring TL6 may be disposed on the other side of the pair of third sub-pixels SP3. For example, the fifth signal wiring TL5 may be disposed adjacent to the fourth signal wiring TL4. The sixth signal wiring TL6 may be disposed adjacent to the first signal wiring TL1 connected to the adjacent pixel PX. The fifth signal wiring TL5 may be electrically connected to the first electrode CE1 of one of the pair of third sub-pixels SP3, for example, the 3-1st sub-pixel SP3a. The sixth signal wiring TL6 may be electrically connected to the first electrode CE1 of the remaining of the third sub-pixel SP3 of the pair of third sub-pixels SP3, for example, the 3-2nd sub-pixel SP3b.

The plurality of signal wirings TL may be made of a conductive material. For example, the plurality of signal wirings TL may be made of a conductive material such as titanium (Ti), aluminum (Al), copper (Cu), molybdenum (Mo), nickel (Ni), chromium (Cr), indium tin oxide (ITO), indium zinc oxide (IZO), indium gallium zinc oxide (IGZO), etc., but the example embodiments of the present disclosure are not limited thereto. For another example, the plurality of signal wirings TL may be composed of a multilayer structure of a conductive material. For example, the plurality of signal wirings TL may be composed of a multilayer structure of titanium (Ti)/aluminum (Al)/titanium (Ti)/indium tin oxide (ITO), but the example embodiments of the present disclosure are not limited thereto.

The plurality of communication wirings NL may be disposed in an area between the plurality of pixels PX. The plurality of communication wirings NL may be disposed to extend in a row direction in the area between the plurality of pixels PX. The plurality of communication wirings NL is disposed in an area between the plurality of second electrodes CE2, and may not overlap the plurality of second electrodes CE2. For example, the plurality of communication wirings NL may be wirings used for short-range communication such as near field communication (NFC). The plurality of communication wirings NL may function as an antenna. For example, the plurality of communication wirings NL may be a plurality of connection wirings, etc., but the example embodiments of the present disclosure are not limited thereto.

According to the present disclosure, the plurality of banks BNK may be disposed on each of the sub-pixels. The plurality of banks BNK may be a structure on which the plurality of micro-LEDs ED is seated. The plurality of banks BNK may guide positions of the plurality of micro-LEDs ED in a transfer process of transferring the plurality of micro-LEDs ED to the display apparatus 1000. In the transfer process of the plurality of micro-LEDs ED, the plurality of micro-LEDs ED may be transferred onto the plurality of banks BNK. The plurality of banks BNK may be a bank pattern, a structure, etc., but the example embodiments of the present disclosure are not limited thereto.

The bank BNK of the first sub-pixel SP1, the bank BNK of the second sub-pixel SP2, and the bank BNK of the third sub-pixel SP3 may be disposed to be spaced apart from each other. The bank BNK of the first sub-pixel SP1, the bank BNK of the second sub-pixel SP2, and the bank BNK of the third sub-pixel SP3 may be configured to be separated from each other. Accordingly, the banks BNK of the first sub-pixel SP1, the second sub-pixel SP2, and the third sub-pixel SP3 to which different types of micro-LEDs ED are transferred may be easily identified.

The bank BNK of the 1-1st sub-pixel SP1a and the bank BNK of the 1-2nd sub-pixel SP1b may be connected to each other, or formed to be spaced apart or separated from each other. For example, considering the design of the transfer process requirements, etc., the bank BNK of the 1-1st sub-pixel SP1a and the bank BNK of the 1-2nd sub-pixel SP1b where the identical micro-LEDs ED are disposed may be connected to each other, or spaced apart or separated from each other. And, the bank BNK of the 2-1st sub-pixel SP2a and the bank BNK of the 2-2nd sub-pixel SP2b may be connected to each other, or formed to be spaced apart or separated from each other. The bank BNK of the 3-1st sub-pixel SP3a and the bank BNK of the 3-2nd sub-pixel SP3b may be connected to each other, or may be formed to be spaced apart or separated from each other. Accordingly, the bank BNK of the pair of first sub-pixels SP1, the bank BNK of the pair of second sub-pixels SP2, and the bank BNK of the pair of third sub-pixels SP3 may be formed in various ways, and the example embodiments of the present disclosure are not limited thereto.

For example, the plurality of banks BNK may be made of an organic insulating material. The plurality of banks BNK may be composed of a single layer or multiple layers of an organic insulating material. For example, the plurality of banks BNK may be made of a photo resist, a polyimide PI, an acrylic material, etc., but the example embodiments of the present disclosure are not limited thereto.

The first electrode CE1 may be disposed on each of the plurality of sub-pixels. The first electrode CE1 may be disposed on the bank BNK. The first electrode CE1 may be electrically connected to one of the plurality of signal wirings TL. At least some of the first electrodes CE1 may extend outside the bank BNK and be electrically connected to the signal wiring TL most adjacent to the first electrode CE1. For example, some of the first electrodes CE1 of the 1-1st sub-pixel SP1a may extend to an area of one side of the 1-1st sub-pixel SP1a and may be electrically connected to the first signal wiring TL1, and some of the first electrodes CE1 of the 1-2nd sub-pixel SP1b may extend to an area of the other side of the 1-2nd sub-pixel SP1b and may be electrically connected to the second signal wiring TL2. Some of the first electrodes CE1 of the 2-1st sub-pixel SP2a may extend to an area of one side of the 2-1st sub-pixel SP2a and may be electrically connected to the third signal wiring TL3, and some of the first electrodes CE1 of the 2-2nd sub-pixel SP2b may extend to an area of the other side of the 2-2nd sub-pixel SP2b and may be electrically connected to the fourth signal wiring TL4. Some of the first electrodes CE1 of the 3-1st sub-pixel SP3a may extend to an area of one side of the 3-1st sub-pixel SP3a and may be electrically connected to the fifth signal wiring TL5, and some of the first electrodes CE1 of the 3-2nd sub-pixel SP3b may extend to an area of the other side of the 3-2nd sub-pixel SP3b and may be electrically connected to the sixth signal wiring TL6.

The first electrode CE1 may be disposed under the micro-LED ED, may be electrically connected to the anode electrode 134 of the micro-LED ED, and may transmit the anode voltage from the pixel driving circuit PD to the micro-LED ED through the signal wiring TL. Different voltages may be applied to the first electrodes CE1 of each of the plurality of sub-pixels depending on the image to be displayed. For example, different voltages may be applied to the first electrodes CE1 of each of the plurality of sub-pixels. Accordingly, the first electrode CE1 may be a pixel electrode, and the example embodiments of the present disclosure are not limited thereto.

The first electrode CE1 may be made of a conductive material. For example, the first electrode CE1 may be formed integrally with the plurality of signal wirings TL. For example, the first electrode CE1 may be made of the same conductive material as the plurality of signal wirings TL, but the example embodiments of the present disclosure are not limited thereto. For example, the first electrode CE1 may be made of a conductive material such as titanium (Ti), aluminum (Al), copper (Cu), molybdenum (Mo), nickel (Ni), chromium (Cr), indium tin oxide (ITO), indium zinc oxide (IZO), indium gallium zinc oxide (IGZO), etc., but the example embodiments of the present disclosure are not limited thereto. For another example, the first electrode CE1 may be composed of a multilayer structure of a conductive material. For example, the plurality of first electrode CE1 may be composed of a multilayer structure of titanium (Ti)/aluminum (Al)/titanium (Ti)/indium tin oxide (ITO), but the example embodiments of the present disclosure are not limited thereto.

The micro-LED ED may be disposed in each of the plurality of sub-pixels. The plurality of micro-LEDs ED may be either a light-emitting diode (LED) or a micro light-emitting diode (micro-LED), but the example embodiments of the present disclosure are not limited thereto. The plurality of micro-LEDs ED may be disposed on the bank BNK and the first electrode CE1. The plurality of micro-LEDs ED may be disposed on the first electrode CE1 and may be electrically connected to the first electrode CE1. Accordingly, the micro-LEDs ED may receive the anode voltage from the pixel driving circuit PD through the signal wiring TL and the first electrode CE1 to emit light.

The plurality of micro-LEDs ED may include a first micro-LED 130, a second micro-LED 140, and a third micro-LED 150. The first micro-LED 130 may be disposed in the first sub-pixel SP1. The second micro-LED 140 may be disposed in the second sub-pixel SP2. The third micro-LED 150 may be disposed in the third sub-pixel SP3. For example, any one of the first micro-LED 130, the second micro-LED 140, and the third micro-LED 150 may be a red micro-LED, the other may be a green micro-LED, and the remaining may be a blue micro-LED, but the example embodiments of the present disclosure are not limited thereto. Accordingly, red light, green light, and blue light emitted from the plurality of micro-LEDs ED may be combined to implement light of various colors including white. The types of the plurality of micro-LEDs ED are examples, and the example embodiments of the present disclosure are not limited thereto.

The first micro-LED 130 may include a 1-1st micro-LED 130a disposed in a 1-1st sub-pixel SP1a and a 1-2nd micro-LED 130b disposed in a 1-2nd sub-pixel SP1b. The second micro-LED 140 may include a 2-1st micro-LED 140a disposed in the 2-1st sub-pixel SP2a and a 2-2nd micro-LED 140b disposed in the 2-2nd sub-pixel SP2b. The third micro-LED 150 may include a 3-1 st micro-LED 150a disposed in the 3-1st sub-pixel SP3a and a 3-2nd micro-LED 150b disposed in the 3-2nd sub-pixel SP3b.

Referring to FIGS. 5 and 6, and FIG. 7 together, the second electrode CE2 may be disposed on each of the plurality of sub-pixels. The second electrode CE2 may be disposed on the micro-LED ED. The second electrode CE2 may be electrically connected to the pixel driving circuit PD through a plurality of contact electrodes CCE.

For example, the second electrode CE2 may be electrically connected to the cathode electrode 135 (see FIG. 9) of the micro-LED ED to transmit a cathode voltage from the pixel driving circuit PD to the micro-LED ED. The same cathode voltage may be applied to the second electrodes CE2 of each of the plurality of sub-pixels. For example, the same voltage may be applied to the second electrodes CE2 of each of the plurality of sub-pixels and the cathode electrode 135 of the micro-LED ED. Accordingly, the second electrode CE2 may be a common electrode, but the example embodiments of the present disclosure are not limited thereto.

At least some of the plurality of sub-pixels may share the second electrode CE2. At least some of the second electrodes CE2 of each of the plurality of sub-pixels may be electrically connected to each other. Since the same voltage is applied to the second electrodes CE2, the second electrodes CE2 of at least some of the sub-pixels may be shared and used. For example, the second electrodes CE2 of at least some of the pixels PX among the plurality of pixels PX disposed in the same row may be connected to each other. For example, one second electrode CE2 may be disposed in the plurality of pixels PX. One second electrode CE2 may be disposed for every n sub-pixels.

For example, some of the second electrodes CE2 of each of the plurality of sub-pixels may be disposed to be spaced apart or separated from each other. For example, the second electrodes CE2 connected to pixels PX of an nth row and the second electrodes CE2 connected to pixels PX of an n+1th row may be disposed to be spaced apart or separated from each other. For example, the plurality of second electrodes CE2 may be disposed to be spaced apart from each other with the plurality of communication wirings NL extending in the row direction therebetween. Accordingly, the number of sub-pixels may be greater than the number of second electrodes CE2. For another example, all of the second electrodes CE2 of the plurality of sub-pixels may be connected to each other so that only one second electrode CE2 may be disposed on the substrate 110, and the example embodiments of the present disclosure are not limited thereto.

The plurality of second electrodes CE2 may be made of a transparent conductive material, but the example embodiments of the present disclosure are not limited thereto. The plurality of second electrodes CE2 may be made of a transparent conductive material so that the light emitted from the micro-LED ED may be directed toward the upper portion of the second electrode CE2. For example, the second electrode CE2 may be made of a transparent conductive material such as indium tin oxide (ITO), indium zinc oxide (IZO), and indium gallium zinc oxide (IGZO), but the example embodiments of the present disclosure are not limited thereto.

The plurality of contact electrodes CCE may be disposed on the substrate 110. For example, the plurality of contact electrodes CCE may be disposed to be spaced apart from the plurality of banks BNK and the plurality of signal wirings TL. Each of the plurality of second electrodes CE2 may overlap at least one contact electrode CCE. For example, one second electrode CE2 may overlap the plurality of contact electrodes CCE.

For example, the plurality of contact electrodes CCE may be electrically connected to the plurality of second electrodes CE2. The plurality of contact electrodes CCE may be disposed between the substrate 110 and the plurality of second electrodes CE2 to transmit the cathode voltage from the pixel driving circuit PD to the second electrodes CE2.

For example, when using the micro-LED as the micro-LED ED, the plurality of micro-LEDs may be formed on a wafer and the micro-LEDs may be transferred to the substrate 110 of the display apparatus 1000 to manufacture the display apparatus 1000. In the process of transferring the plurality of micro-LEDs ED having a micro size from the wafer to the substrate 110, various defects may occur. For example, in some sub-pixels, a non-transfer defect may occur in which the micro-LED ED is not transferred, and in some other sub-pixels, a defect may occur in which the micro-LED ED is transferred out of its proper position due to an alignment error. In addition, although the transfer process is performed normally, the transferred micro-LED ED itself may be defective. Therefore, the plurality of identical micro-LEDs ED may be transferred to one sub-pixel in consideration of the defect during the process of transferring the plurality of micro-LEDs ED. A lighting test of the plurality of micro-LEDs ED may be performed, and only one micro-LED ED that is ultimately determined to be normal may be used.

For example, the 1-1st micro-LED 130a and the 1-2nd micro-LED 130b may be transferred together to one pixel PX, and it may be tested whether the 1-1st micro-LED 130a and the 1-2nd micro-LED 130b are defective. If both the 1-1st micro-LED 130a and the 1-2nd micro-LED 130b are determined to be normal, only the 1-1st micro-LED 130a may be used, and the 1-2nd micro-LED 130b may not be used. For another example, when only the 1-2nd micro-LED 130b among the 1-1st micro-LED 130a and the 1-2nd micro-LED 130b is determined to be normal, the 1-1st micro-LED 130a may not be used, and only the 1-2nd micro-LED 130b may be used. Accordingly, even if the plurality of identical micro-LEDs ED is transferred to one pixel PX, only one micro-LED ED may be used ultimately.

Accordingly, any one of the pair of micro-LEDs ED may be a main (or primary) micro-LED ED, and the other micro-LED ED may be a redundancy micro-LED ED. The redundancy micro-LED ED may be a spare micro-LED ED transferred in preparation for the defect of the main micro-LED ED. In the event of the defect of the main micro-LED ED, the redundancy micro-LED ED may be used as a replacement. Therefore, by transferring the main micro-LED ED and the redundancy micro-LED ED together to one pixel PX, the deterioration in display quality due to the defect of the main micro-LED ED and the redundancy micro-LED ED may be minimized or reduced.

For example, the 1-1st micro-LED 130a, the 2-1nd micro-LED 140a, and the 3-1st micro-LED 150a transferred to one pixel PX may be used as the main micro-LED ED, and the 1-2nd micro-LED 130b, the 2-2nd micro-LED 140b, and the 3-2nd micro-LED 150b may be used as the redundancy micro-LED ED.

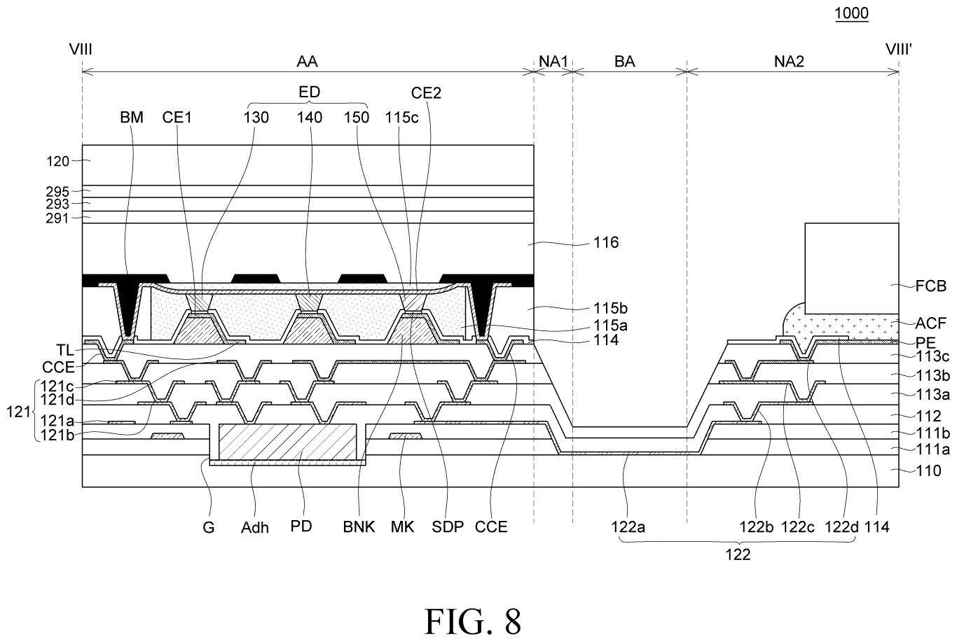

FIG. 8 is a cross-sectional view taken along line VIII-VIII′ of FIG. 3. FIG. 9 is a cross-sectional view of the display apparatus according to an example embodiment of the present disclosure. FIG. 8 is a cross-sectional view of the display apparatus according to an example embodiment of the present disclosure. For example, FIG. 8 is a cross-sectional view of the display area AA, the first non-display area NA1, the bending area BA, and the second non-display area NA2. For example, FIG. 9 is an enlarged cross-sectional view of the first sub-pixel. Meanwhile, for convenience of illustration, in FIG. 3, the cutting line of VIII-VIII′ and the driving wiring VL and the link wiring LL are illustrated as not overlapping, but the cutting line of VIII-VIII′ of FIG. 3 is intended to indicate the same position as the adjacent driving wiring VL and the link wiring LL.

Referring to FIG. 8, the substrate 110 may include a groove G. The groove G is a location where the pixel driving circuit PD is mounted, and may be disposed in the display area AA where the pixel driving circuit PD is disposed. Since the plurality of pixel driving circuits PD is disposed on the substrate 110, a plurality of grooves G for mounting the plurality of pixel driving circuits PD may also be disposed.

Meanwhile, the groove G may be formed by partially removing the substrate 110 in a thickness direction. Accordingly, a thickness of the substrate 110 in the area overlapping the groove G may be thicker than that of the substrate 110 in the remaining area. A width of the groove G may be greater than that of the pixel driving circuit PD so that the pixel driving circuit PD may be mounted, but is not limited thereto.

The pixel driving circuit PD may be disposed on the groove G in the display area AA. Specifically, the plurality of pixel driving circuits PD may each be disposed on each of the plurality of grooves G. The pixel driving circuit PD may be fixed to the groove G of the substrate 110 by an adhesive pattern Adh. When the pixel driving circuit PD is implemented as a driving driver, the driving driver may be mounted on the groove G of the substrate 110 by the transfer process, but the example embodiments of the present disclosure are not limited thereto.

The adhesive pattern Adh may be disposed on the substrate 110. Specifically, the adhesive pattern Adh may be disposed between the substrate 110 and the pixel driving circuit PD to fix the pixel driving circuit PD in the groove G. The adhesive pattern Adh may be disposed only in a minimum area necessary to suppress unnecessary foreign materials from being attached onto the adhesive pattern Adh during the process. The adhesive pattern Adh may be disposed, for example, only in the groove G where the pixel driving circuit PD is disposed. The adhesive pattern Adh may be disposed only in the groove G where the pixel driving circuit PD is disposed, and disposed only in a portion of the display area AA, but is not limited thereto. A width of the adhesive pattern Adh may be the same as that of the groove G, but is not limited thereto.

The adhesive pattern Adh may be made of an organic insulating material. For example, the adhesive pattern Adh may be made of any one of an adhesive polymer, an epoxy resin, a UV-curable resin, a polyimide series, an acrylate series, a urethane series, and a polydimethylsiloxane PDMS, but the example embodiments of the present disclosure are not limited thereto.

Meanwhile, the adhesive pattern Adh may be disposed on the substrate 110 and may be in direct contact with the substrate 110. As described above, the adhesive pattern Adh and the substrate 110 may both be made of an organic insulating material. Therefore, since the adhesive pattern Adh and the substrate 110 made of the same series of materials are in contact with each other, an adhesive strength between the adhesive pattern Adh and the substrate 110 may be improved.

A first buffer layer 111a and a second buffer layer 111b may be disposed in the remaining area of the substrate 110 excluding the bending area BA.

The first buffer layer 111a and the second buffer layer 111b may be disposed in the display area AA, the first non-display area NA1, and the second non-display area NA2.

Specifically, the first buffer layer 111a and the second buffer layer 111b may be disposed in an area excluding the groove G of the substrate 110 in the display area AA. That is, the first buffer layer 111a and the second buffer layer 111b may be disposed to surround an area where the groove G is disposed in the display area AA, and may be disposed to surround the pixel driving circuit PD disposed in the groove G.

Meanwhile, the first buffer layer 111a and the second buffer layer 111b may be disposed in an area excluding the groove G, and may be disposed on a relatively thick area of the substrate 110. Accordingly, the first buffer layer 111a and the second buffer layer 111b may be disposed at a relatively higher position than the adhesive pattern Adh disposed in the groove G, which is a relatively thin area of the substrate 110, but is not limited thereto.

Accordingly, the bottom surface of the first buffer layer 111a and the second buffer layer 111b may be disposed at a higher position than that of the pixel driving circuit PD disposed on the adhesive pattern Adh in the groove G, but is not limited thereto.

The first buffer layer 111a and the second buffer layer 111b may reduce the penetration of moisture or impurities through the substrate 110. The first buffer layer 111a and the second buffer layer 111b may be made of an inorganic insulating material, and may be referred to as inorganic insulating layer. The adhesive pattern Adh may be disposed to be spaced apart from the inorganic insulating layer. For example, the first buffer layer 111a and the second buffer layer 111b may be composed of a single layer or multiple layers of silicon oxide SiOx or silicon nitride SiNx, but the example embodiments of the present disclosure are not limited thereto.

For example, the first buffer layer 111a and the second buffer layer 111b on the bending area BA may be partially removed. A top surface of the substrate 110 located in the bending area BA may be exposed from the first buffer layer 111a and the second buffer layer 111b. By removing the first buffer layer 111a and the second buffer layer 111b made of an inorganic insulating material from the bending area BA, it is possible to minimize or reduce cracks in the first buffer layer 111a and the second buffer layer 111b that may occur during bending.

A plurality of alignment keys MK may be disposed between the first buffer layer 111a and the second buffer layer 111b. The plurality of alignment keys MK may be configured to identify a position of the pixel driving circuit PD during the process of manufacturing the display apparatus 1000. For example, the plurality of alignment keys MK may be configured to align the position of the pixel driving circuit PD transferred on the groove G of the substrate 110. In another example, the plurality of alignment keys MK may be omitted.

For example, the plurality of alignment keys MK may be disposed on the first buffer layer 111a. In this case, since the first buffer layer 111a on which the plurality of alignment keys MK is disposed is disposed in a relatively thick area on the substrate 110, and compared to the pixel driving circuit PD disposed in the groove G, which is the relatively thin area, a bottom surface of the plurality of alignment keys MK may be disposed at a relatively higher position than that of the pixel driving circuit PD, but is not limited thereto.

According to the present disclosure, a plurality of first connection wirings 121 may be disposed on the second buffer layer 111b in the display area AA. The plurality of first connection wirings 121 may be wiring for electrically connecting the pixel driving circuit PD to other components. For example, the pixel driving circuit PD may be electrically connected to the plurality of signal wirings TL, the plurality of contact electrodes CCE, etc., through the plurality of first connection wirings 121. For example, the plurality of first connection wirings 121 may include a 1-1st connection wiring 121a, a 1-2nd connection wiring 121b, a 1-3rd connection wiring 121c, and a 1-4th connection wiring 121d, but the example embodiments of the present disclosure are not limited thereto.

For example, the plurality of 1-1st connection wirings 121a may be disposed on the second buffer layer 111b and may be in contact with the second buffer layer 111b. The plurality of 1-1st connection wirings 121a may be electrically connected to the pixel driving circuit PD. The plurality of 1-1st connection wirings 121a may transmit the voltage output from the pixel driving circuit PD to the first electrode CE1 or the second electrode CE2.

For example, a protection layer 112 may be disposed on the first buffer layer 111a, the second buffer layer 111b, and the pixel driving circuit PD. The protection layer 112 may be disposed entirely over the display area AA and the non-display area NA.

The protection layer 112 may be made of an organic insulating material. For example, the protection layer 112 may be made of a photo resist, a polyimide PI, a photo acryl-based material, etc., but the example embodiments of the present disclosure are not limited thereto. Accordingly, the protection layer 112 may be referred to as an organic insulating layer, but is not limited thereto.

Meanwhile, a portion of the protection layer 112 may be disposed to extend to the groove G. Specifically, a portion of the protection layer 112 may be disposed to fill a gap between the pixel driving circuit PD and the first buffer layer 111a and the second buffer layer 111b in the groove G. Accordingly, a portion of the protection layer 112 may be disposed to remove air bubbles between the pixel driving circuit PD and the first buffer layer 111a and the second buffer layer 111b in the groove G and surround a side surface of the pixel driving circuit PD, thereby fixing and protecting the pixel driving circuit PD.

In addition, a portion of the protection layer 112 may be in contact with the adhesive pattern Adh in the groove G. Since both the protection layer 112 and the adhesive pattern Adh are made of an organic insulating material, it is possible to improve the adhesive strength between the protection layer 112 and the adhesive pattern Adh. Accordingly, the pixel driving circuit PD may be fixed more effectively by the adhesive pattern Adh disposed in the groove G.

A plurality of 1-2nd connection wirings 121b may be disposed on the protection layer 112. The plurality of 1-2nd connection wirings 121b may be indirectly or directly connected to the pixel driving circuit PD. For example, a portion of the 1-2nd connection wirings 121b may be directly connected to the pixel driving circuit PD through the contact hole of a protection layer 112. The other portion of the 1-2nd connection wirings 121b may be electrically connected to the 1-1st connection wiring 121a through the contact hole of the protection layer 112. However, the example embodiments of the present disclosure are not limited thereto. The voltage output from the pixel driving circuit PD may be transmitted to the first electrode CEL or the second electrode CE2 through the plurality of 1-2nd connection wirings 121b and other connection wirings.

A first insulating layer 113a may be disposed on a plurality of 1-2nd connection wirings 121b. The first insulating layer 113a may be disposed entirely in the display area AA and the non-display area NA, but the example embodiments of the present disclosure are not limited thereto. The first insulating layer 113a may be made of an organic insulating material, but the example embodiments of the present disclosure are not limited thereto. For example, the first insulating layer 113a may be composed of the photo resist, the polyimide PI, the photo acryl-based material, etc., but the example embodiments of the present disclosure are not limited thereto. Accordingly, the first insulating layer 113a may be referred to as a first organic insulating layer, but is not limited thereto.

A plurality of 1-3rd connection wirings 121c may be disposed on the first insulating layer 113a. The plurality of 1-3rd connection wirings 121c may be electrically connected to the plurality of 1-2nd connection wirings 121b. For example, the 1-3rd connection wirings 121c may be electrically connected to the 1-2nd connection wirings 121b through the contact hole of the first insulating layer 113a.

A second insulating layer 113b may be disposed on the plurality of 1-3rd connection wirings 121c. The second insulating layer 113b may be disposed in the remaining area excluding the bending area BA, but the example embodiments of the present disclosure are not limited thereto. The second insulating layer 113b may be disposed in the display area AA, the first non-display area NA1, and the second non-display area NA2, but the example embodiments of the present disclosure are not limited thereto. For example, the second insulating layer 113b disposed in the bending area BA may be partially removed. The second insulating layer 113b may be made of an organic insulating material, but the example embodiments of the present disclosure are not limited thereto. For example, the second insulating layer 113b may be made of the photo resist, the polyimide PI, the photo acryl-based material, etc., but the example embodiments of the present disclosure are not limited thereto. Accordingly, the second insulating layer 113b may be referred to as a second organic insulating layer, but is not limited thereto.

A plurality of 1-4th connection wirings 121d may be disposed on the second insulating layer 113b. The plurality of 1-4th connection wirings 121d may be electrically connected to the plurality of 1-3rd connection wirings 121c. For example, the 1-4th connection wirings 121d may be electrically connected to the 1-3rd connection wirings 121c through the contact hole of the second insulating layer 113b.

According to the present disclosure, the plurality of 2nd connection wirings 122 may be disposed on the second buffer layer 111b in the non-display area NA. The plurality of second connection wirings 122 may be wirings for transmitting a signal, which is transmitted from the flexible circuit board (or flexible film) FCB and the printed circuit board 160 (see FIG. 1) to the pad part PAD, to the pixel driving circuit PD of the display area AA. For example, the plurality of second connection wirings 122 may be electrically connected to the plurality of pad electrodes PE to receive the signal from the flexible circuit board (or flexible film) FCB and the printed circuit board.

For example, the plurality of second connection wirings 122 may extend from the pad part PAD toward the display area AA to transmit signals to the wiring of the display area AA. In this case, the plurality of second connection wirings 122 may function as the link wirings LL. The plurality of second connection wirings 122 may include a 2-1st connection wiring 122a, a 2-2nd connection wiring 122b, a 2-3rd connection wiring 122c, and a 2-4th connection wiring 122d.

The plurality of 2-1st connection wirings 122a may be disposed on the second buffer layer 111b. The plurality of 2-1st connection wirings 122a may extend from the second non-display area NA2 to the bending area BA and the first non-display area NA1. Accordingly, the 2-1st connection wiring 122a may be in contact with the first buffer layer 111a and the second buffer layer 111b in the display area AA, the first non-display area NA1, and the second non-display area NA2, while the 2-1st connection wiring 122a may be in contact with the substrate 110 in the bending area BA, but are not limited thereto. The plurality of 2-1st connection wirings 122a may transmit a signal, which is transmitted from the flexible circuit board (or flexible film) FCB and the printed circuit board 160 to the pad part PAD, to the pixel driving circuit PD of the display area AA. For example, the 2-1st connection wiring 122a extends from the second non-display area NA2 to the first non-display area NA1, and may be electrically connected to any one of the 1-1st connection wiring 121a, the 1-2nd connection wiring 121b, the 1-3rd connection wiring 121c, and the 1-4th connection wiring 121d of the plurality of first connection wirings 121. For example, the 2-1st connection wiring 122a may be directly connected to the 1-1st connection wiring 121a disposed on the same layer, or may be connected to the 1-2nd connection wiring 121b disposed in a different layer through a contact hole of the third passivation layer 114, but is not limited thereto.

The plurality of 2-2nd connection wirings 122b may be disposed on the protection layer 112. The plurality of 2-2nd connection wirings 122b may be disposed in the second non-display area NA2. The 2-2nd connection wirings 122b may be electrically connected to the 2-1st connection wirings 122a through the contact hole of the third protection layer 112. Accordingly, the signal from the flexible circuit board (or flexible film) FCB and the printed circuit board may be transmitted to the 2-1st connection wiring 122a through the 2-2nd connection wirings 122b.

The 2-3rd connection wiring 122c may be disposed on the first insulating layer 113a. The 2-3rd connection wirings 122c may be disposed in the second non-display area NA2. The 2-3rd connection wiring 122c may be electrically connected to the 2-2nd connection wiring 122b through the contact hole of the first insulating layer 113a. Accordingly, the signal from the flexible circuit board (or flexible film) FCB and the printed circuit board may be transmitted to the 2-1st connection wiring 122a through the 2-3rd connection wiring 122c and the 2-2nd connection wiring 122b.

The 2-4th connection wiring 122d may be disposed on the second insulating layer 113b. The 2-4th connection wiring 122d may be disposed in the second non-display area NA2. The 2-4th connection wiring 122d may be electrically connected to the 2-3rd connection wiring 122c through the contact hole of the second insulating layer 113b. Accordingly, the signal from the flexible circuit board (or flexible film) FCB and the printed circuit board 160 may be transmitted to the 2-1st connection wiring 122a through the 2-4th connection wiring 122d, the 2-3rd connection wiring 122c, and the 2-2nd connection wiring 122b.

The plurality of first connection wirings 121 and the plurality of second connection wirings 122 may be made of a conductive material having excellent flexibility or any one of various conductive materials used in the display area AA. For example, the second connection wiring 122, a portion of which is disposed in the bending area BA, may be formed of a conductive material having excellent flexibility, such as gold (Au), silver (Ag), or aluminum (Al), but the example embodiments of the present disclosure are not limited thereto. For another example, the plurality of first connection wirings 121 and the plurality of second connection wirings 122 may be made of molybdenum (Mo), chromium (Cr), titanium (Ti), nickel (Ni), neodymium (Nd), copper (Cu), and an alloy of silver (Ag) and magnesium (Mg), or an alloy thereof, but the example embodiments of the present disclosure are not limited thereto.

A third insulating layer 113c may be disposed on the plurality of first connection wirings 121 and the plurality of second connection wirings 122. The third insulating layer 113c may be disposed in an area other than the bending area BA, but the example embodiments of the present disclosure are not limited thereto. The third insulating layer 113c may be disposed in the display area AA, the first non-display area NA1, and the second non-display area NA2. The third insulating layer 113c in the bending area BA may be partially removed. The third insulating layer 113c may be made of an organic insulating material, but the example embodiments of the present disclosure are not limited thereto. For example, the third insulating layer 113c may be made of a photo resist, a polyimide PI, a photo acryl-based material, etc., but the example embodiments of the present disclosure are not limited thereto. Accordingly, the third insulating layer 113c may be referred to as a third organic insulating layer, but is not limited thereto.

The number of insulating layers disposed in the bending area BA may be less than the number of insulating layers disposed in the display area AA, the first non-display area NA1, and the second non-display area NA2. For example, the first insulating layer 113a may be disposed in all of the display area AA, the first non-display area NA1, the bending area BA, and the second non-display area NA2. On the other hand, the second insulating layer 113b and the third insulating layer 113c may be disposed in the display area AA, the first non-display area NA1, and the second non-display area NA2 excluding the bending area BA. Accordingly, the height of the insulating layer disposed in the bending area BA may be relatively lower than that in the area excluding the bending area BA, but is not limited thereto.

The plurality of banks BNK may be disposed on the third insulating layer 113c in the display area AA. The plurality of banks BNK may be disposed to overlap each of the plurality of sub-pixels. One or more identical micro-LEDs ED may be disposed above each of the plurality of banks BNK.

The plurality of signal wirings TL may be disposed on the third insulating layer 113c in the display area AA. The plurality of signal wirings TL may be disposed in an area between the plurality of banks BNK. For example, the plurality of signal wirings TL may be disposed adjacent to any one of the plurality of banks BNK.

The plurality of contact electrodes CCE may be disposed on the third insulating layer 113c in the display area AA. The plurality of contact electrodes CCE may supply the cathode voltage from the pixel driving circuit PD to the second electrode CE2.

The first electrode CE1 may be disposed on the bank BNK. For example, the first electrode CE1 may be disposed to extend from the adjacent signal wiring TL toward the upper portion of the bank BNK. The first electrode CE1 may be disposed on the top surface of the bank BNK and the side surfaces of the bank BNK. For example, the first electrode CE1 may be disposed to extend from the signal wiring TL of the top surface of the third insulating layer 113c to the side surfaces of the bank BNK and the top surface of the bank BNK.

Referring to FIG. 9, the first electrode CE1 may be composed of a plurality of conductive layers. For example, the first electrode CE1 may include a first conductive layer CE1a, a second conductive layer CE1b, a third conductive layer CE1c, and a fourth conductive layer CE1d, but the example embodiments of the present disclosure are not limited thereto.

The first conductive layer CE1a may be disposed on the bank BNK. The second conductive layer CE1b may be disposed on the first conductive layer CE1a. The third conductive layer CE1c may be disposed on the second conductive layer CE1b, and the fourth conductive layer CE1d may be disposed on the third conductive layer CE1c. For example, each of the first conductive layer CE1a, the second conductive layer CE1b, the third conductive layer CE1c, and the fourth conductive layer CE1d may be made of titanium (Ti), molybdenum (Mo), aluminum (Al), or titanium (Ti) and indium tin oxide (ITO), but the example embodiments of the present disclosure are not limited thereto.

According to the present disclosure, some of the conductive layers having high reflection efficiency among the plurality of conductive layers constituting the first electrode CE1 may be configured as an alignment key and/or a reflector for aligning the micro-LEDs ED. For example, the second conductive layer CE1b among the plurality of conductive layers of the first electrode CE1 may include a reflective material. For example, the second conductive layer CE1b may include aluminum (Al), but the example embodiments of the present disclosure are not limited thereto. Accordingly, the second conductive layer CE1b may be configured as a reflector. In addition, due to the high reflection efficiency of the second conductive layer CE1b, it may be easily identified in the manufacturing process, and thus the position or transfer position of the micro-LED ED may be aligned based on the second conductive layer CE1b.

For example, in order to configure the second conductive layer CE1b as the reflector, the third conductive layer CE1c and the fourth conductive layer CE1d covering the second conductive layer CE1b may be partially removed or etched. For example, the third conductive layer CE1c and the fourth conductive layer CE1d disposed on the bank BNK may be partially removed or etched to expose the top surface of the second conductive layer CE1b. For example, the central portion and corner portion (or edge portion) where a solder pattern SDP is disposed in the third conductive layer CE1c and the fourth conductive layer CE1d may be left, and the remaining portions excluding the portions may be removed. For example, the corner portion (or edge portion) of the third conductive layer CE1c made of titanium (Ti) and the fourth conductive layer CE1d made of indium tin oxide (ITO), respectively, may not be etched. Accordingly, it is possible to suppress other conductive layers of the first electrode CE1 from being corroded by a tetramethylammoniumhydroxide (TMAH) solution used in the mask process of the first electrode CE1.

According to the present disclosure, the first conductive layer CE1a and the third conductive layer CE1c may include titanium (Ti) or molybdenum (Mo). The second conductive layer CE1b may include aluminum (Al). The fourth conductive layer CE1d may include a transparent conductive oxide layer such as indium tin oxide (ITO) or indium zinc oxide (IZO) that has good adhesion to the solder pattern SDP, corrosion resistance and acid resistance. However, the example embodiments of the present disclosure are not limited thereto.

The first conductive layer CE1a, the second conductive layer CE1b, the third conductive layer CE1c, and the fourth conductive layer CE1d may be sequentially deposited and then patterned by performing a photolithography process and an etching process, but the example embodiments of the present disclosure are not limited thereto.

According to the present disclosure, the signal wiring TL, the contact electrode CCE, and the pad electrode PE disposed on the same layer as the first electrode CE1 may be composed of multiple layers of a conductive material, but the example embodiments of the present disclosure are not limited thereto. For example, the signal wiring TL, the contact electrode CCE, and the pad electrode PE may be composed of multiple layers of indium tin oxide (ITO)/titanium (Ti)/aluminum (Al)/titanium (Ti), but the example embodiments of the present disclosure are not limited thereto.

According to the present disclosure, the solder pattern SDP may be disposed on the first electrode CE1 in each of the plurality of sub-pixels. The solder pattern SDP may electrically connect the first electrode CE1 and the micro-LED ED by bonding the micro-LED ED to the first electrode CE1. For example, the first electrode CE1 and the anode electrode 134 of the micro-LED ED may be electrically connected through the eutectic bonding using the solder pattern SDP, but the example embodiments of the present disclosure are not limited thereto. For example, when the solder pattern SDP is made of indium (In) and the anode electrode 134 of the micro-LED ED is made of gold (Au), the solder pattern SDP and the anode electrode 134 may be bonded by applying heat and pressure during the transfer process of the micro-LED ED. Through eutectic bonding, the micro-LED ED may be bonded to the solder pattern SDP and the first electrode CE1 without a separate adhesive. For example, the solder pattern SDP may be made of indium (In), tin (Sn), or an alloy thereof, but the example embodiments of the present disclosure are not limited thereto. For example, the solder pattern SDP may be a bonding pad, a soldering pad, etc., but the example embodiments of the present disclosure are not limited thereto.

According to the present disclosure, the passivation layer 114 may be disposed on the plurality of signal wirings TL, the plurality of first electrodes CE1, the plurality of contact electrodes CCE, and the third insulating layer 113c. For example, the passivation layer 114 may be disposed in the display area AA, the first non-display area NA1, and the second non-display area NA2. The passivation layer 114 disposed in the bending area BA may be partially removed. The passivation layer 114 covering the plurality of pad electrodes PE in the second non-display area NA2 may be partially removed. Since the passivation layer 114 is disposed to cover the remaining area excluding the area where the bending area BA, the plurality of pad electrodes PE, and the solder pattern SDP are disposed, it is possible to reduce the penetration of moisture or impurities into the micro-LED ED. For example, the passivation layer 114 may be composed of a single layer or multiple layers of silicon oxide (SiOx) or silicon nitride (SiNx), but the example embodiments of the present disclosure are not limited thereto. For example, the passivation layer 114 may be a passivation layer, an insulating layer, etc., but the example embodiments of the present disclosure are not limited thereto. For example, the passivation layer 114 may include a hole exposing the solder pattern SDP.

The micro-LEDs ED may be disposed on the solder pattern SDP in each of the plurality of sub-pixels. The first micro-LED 130 may be disposed in the first sub-pixel SP1. The second micro-LED 140 may be disposed in the second sub-pixel SP2. The third micro-LED 150 may be disposed in the third sub-pixel SP3.

The micro-LED ED may be formed on a silicon wafer by methods such as metal organic chemical vapor deposition (MOCVD), chemical vapor deposition (CVD), plasma-enhanced chemical vapor deposition (PECVD), molecular beam epitaxy (MBE), hydride vapor phase epitaxy (HVPE), or sputtering, but the example embodiments of the present disclosure are not limited thereto.

Referring to FIG. 9, the first micro-LED 130 may include the anode electrode 134, a first semiconductor layer 131, an active layer 132, a second semiconductor layer 133, the cathode electrode 135, and an encapsulation film 136, but the example embodiments of the present disclosure are not limited thereto. For example, the encapsulation film 136 may not be included in the first micro-LED 130.

The first semiconductor layer 131 may be disposed on the solder pattern SDP. The second semiconductor layer 133 may be disposed on the first semiconductor layer 131.

For example, one of the first semiconductor layer 131 and the second semiconductor layer 133 may be implemented as a compound semiconductor of group III-V, group II-VI, etc., and may be doped with an impurity or dopant. For example, one of the first semiconductor layer 131 and the second semiconductor layer 133 may be a semiconductor layer doped with an n-type impurity, and the other may be a semiconductor layer doped with a p-type impurity, but the example embodiments of the present disclosure are not limited thereto. For example, at least one of the first semiconductor layer 131 and the second semiconductor layer 133 may be a layer in which n-type or p-type impurities are doped in a material such as gallium nitride (GaN), gallium phosphide (GaP), gallium arsenide phosphide (GaAsP), aluminum gallium indium phosphide (AlGaInP), indium aluminum phosphide (InAIP), aluminum gallium nitride (AlGaN), aluminum indium nitride (AlInN), aluminum indium gallium nitride (AlInGaN), aluminum gallium arsenide (AlGaAs), or gallium arsenide (GaAs), but the example embodiments of the present disclosure are not limited thereto. For example, the n-type impurity may be silicon (Si), germanium (Ge), selenium (Se), carbon (C), tellurium (Te), tin (Sn), etc., but the example embodiments of the present disclosure are not limited thereto. For example, the p-type impurity may be magnesium (Mg), zinc (Zn), calcium (Ca), strontium (Sr), barium (Ba), beryllium (Be), etc., but the example embodiments of the present disclosure are not limited thereto.

For example, the first semiconductor layer 131 and the second semiconductor layer 133 may be a nitride semiconductor including an n-type impurity and a nitride semiconductor including a p-type impurity, respectively, but the example embodiments of the present disclosure are not limited thereto. For example, the first semiconductor layer 131 may be a nitride semiconductor including a p-type impurity, and the second semiconductor layer 133 may be a nitride semiconductor including an n-type impurity, but the example embodiments of the present disclosure are not limited thereto.

The active layer 132 may be disposed between the first semiconductor layer 131 and the second semiconductor layer 133. The active layer 132 may receive holes and electrons from the first semiconductor layer 131 and the second semiconductor layer 133 and emit light. For example, the active layer 132 may be configured as one of a single well structure, a multi-well structure, a single quantum well structure, a multi-quantum well (MQW) structure, a quantum dot structure, and a quantum wire structure, but the example embodiments of the present disclosure are not limited thereto. For example, the active layer 132 may be configured as indium gallium nitride (InGaN), gallium nitride (GaN), etc., but the example embodiments of the present disclosure are not limited thereto.

For another example, the active layer 132 may include the multi-quantum well (MQW) structure that has a well layer and a barrier layer having a higher band gap than the well layer. For example, the active layer 132 may be composed of an InGaN layer as the well layer and an AlGaN layer as the barrier layer, but the example embodiments of the present disclosure are not limited thereto.

The anode electrode 134 may be disposed between the first semiconductor layer 131 and the solder pattern SDP. For example, the anode electrode 134 may electrically connect the first semiconductor layer 131 and the first electrode CE1. The anode voltage output from the pixel driving circuit PD may be applied to the first semiconductor layer 131 through the signal wiring TL, the first electrode CE1, and the anode electrode 134. For example, the anode electrode 134 may be made of a conductive material capable of eutectic bonding with the solder pattern SDP, but the example embodiments of the present disclosure are not limited thereto. For example, the anode electrode 134 may be made of gold (Au), tin (Sn), tungsten (W), silicon (Si), silver (Ag), titanium (Ti), iridium (Ir), chromium (Cr), indium (In), zinc (Zn), lead (Pb), nickel (Ni), platinum (Pt), and copper (Cu), an alloy thereof, etc., but the example embodiments of the present disclosure are not limited thereto.

The cathode electrode 135 may be disposed on the second semiconductor layer 133. For example, the cathode electrode 135 may electrically connect the second semiconductor layer 133 and the second electrode CE2. The cathode voltage output from the pixel driving circuit PD may be applied to the second semiconductor layer 133 through the contact electrode CCE, the second electrode CE2, and the cathode electrode 135. The cathode electrode 135 may be made of a transparent conductive material so that the light emitted from the micro-LED ED may be directed toward the upper portion of the micro-LED ED, but the example embodiments of the present disclosure are not limited thereto. For example, the cathode electrode 135 may be made of a material such as indium tin oxide (ITO), indium zinc oxide (IZO), or indium gallium zinc oxide (IGZO), but the example embodiments of the present disclosure are not limited thereto.

The encapsulation film 136 may be disposed on at least a portion of the first semiconductor layer 131, the active layer 132, the second semiconductor layer 133, the anode electrode 134, and the cathode electrode 135. For example, the encapsulation film 136 may surround at least a portion of the first semiconductor layer 131, the active layer 132, the second semiconductor layer 133, the anode electrode 134, and the cathode electrode 135.

For example, the encapsulation film 136 may protect the first semiconductor layer 131, the active layer 132, and the second semiconductor layer 133. For example, the encapsulation film 136 may be disposed on the side surfaces of the first semiconductor layer 131, the side surfaces of the active layer 132, and the side surfaces of the second semiconductor layer 133.

For example, the encapsulation film 136 may be disposed on at least a portion of the anode electrode 134 and the cathode electrode 135, for example, an edge portion (or a corner portion or one side) of the anode electrode 134 and an edge portion (or a corner portion or one side) of the cathode electrode 135. At least a portion of the anode electrode 134 may be exposed from the encapsulation film 136 so that the anode electrode 134 and the solder pattern SDP may be connected. For example, at least a portion of the cathode electrode 135 may be exposed from the encapsulation film 136 so that the cathode electrode 135 and the second electrode CE2 may be connected. For example, the encapsulation film 136 may be made of an insulating material such as silicon nitride (SiNx) or silicon oxide (SiOx), but the example embodiments of the present disclosure are not limited thereto.

For another example, the encapsulation film 136 may have a structure in which a reflective material is dispersed in a resin layer, but the example embodiments of the present disclosure are not limited thereto. For example, the encapsulation film 136 may be manufactured as a reflector of various structures, but the example embodiments of the present disclosure are not limited thereto. The light emitted from the active layer 132 by the encapsulation film 136 may be reflected upward, thereby improving the light extraction efficiency. For example, the encapsulation film 136 may be a reflective layer, but the example embodiments of the present disclosure are not limited thereto.

According to the present disclosure, the micro-LED ED is described as having a vertical type structure, but the example embodiments of the present disclosure are not limited thereto. For example, the micro-LED ED may have a lateral structure or a flip chip structure.

Although the first micro-LED 130 has been described with reference to FIG. 9, the second micro-LED 140 and the third micro-LED 150 may have substantially the same structure as the first micro-LED 130. For example, the second micro-LED 140 and the third micro-LED 150 may have substantially the same structure as the first semiconductor layer 131, the active layer 132, the second semiconductor layer 133, the anode electrode 134, the cathode electrode 135, and the encapsulation film 136 of the first micro-LED 130.

According to the present disclosure, a first optical layer 115a may be disposed to surround the plurality of micro-LEDs ED in the display area AA. For example, the first optical layer 115a may be disposed to cover the plurality of micro-LEDs ED and the bank BNK in the area of the plurality of sub-pixels. For example, the first optical layer 115a may cover between the bank BNK, a portion of the passivation layer 114, and the plurality of micro-LEDs ED. The first optical layer 115a may be disposed or cover between the plurality of micro-LEDs ED included in one pixel PX and the plurality of banks BNK. For example, the first optical layer 115a may extend in a row direction and be disposed to be spaced apart from each other in a column direction. For example, the first optical layer 115a may be disposed to surround the side portions of the micro-LED ED and the bank BNK between the passivation layer 114 and the second electrode CE2, but the example embodiments of the present disclosure are not limited thereto. For example, the first optical layer 115a may be a diffusion layer, a sidewall diffusion layer, etc., but the example embodiments of the present disclosure are not limited thereto.

The first optical layer 115a may include organic insulating materials having fine particles dispersed therein, but the example embodiments of the present disclosure are not limited thereto. For example, the first optical layer 115a may be made of siloxane having fine metal particles, such as titanium dioxide TiO₂ particles dispersed therein, but the example embodiments of the present disclosure are not limited thereto. The light from the plurality of micro-LEDs ED may be scattered by the fine particles dispersed in the first optical layer 115a and emitted to the outside of the display apparatus 1000. Accordingly, the first optical layer 115a may improve the extraction efficiency of the light emitted from the plurality of micro-LEDs ED.

For example, the first optical layer 115a may be disposed on each of the plurality of pixels PX, or may be disposed together on some of the pixels PX disposed in the same row, but the example embodiments of the present disclosure are not limited thereto. For example, the first optical layer 115a may be disposed on each of the plurality of pixels PX, or the plurality of pixels PX may share one first optical layer 115a. For another example, each of the plurality of sub-pixels may separately include the first optical layer 115a, but the example embodiments of the present disclosure are not limited thereto.

According to the present disclosure, the second optical layer 115b may be disposed on the passivation layer 114 in the display area AA. For example, the second optical layer 115b may be disposed to surround the first optical layer 115a. For example, the second optical layer 115b may be in contact with the side surfaces of the first optical layer 115a. For example, the second optical layer 115b may be disposed in the area between the plurality of pixels PX. However, the example embodiments of the present disclosure are not limited thereto. For example, the second optical layer 115b may be a diffusion layer, a diffusion layer window, a window diffusion layer, etc., but the example embodiments of the present disclosure are not limited thereto.

The second optical layer 115b may be made of an organic insulating material, but the example embodiments of the present disclosure are not limited thereto. The second optical layer 115b may be made of the same material as the first optical layer 115a, but the example embodiments of the present disclosure are not limited thereto. For example, the first optical layer 115a may include fine particles, and the second optical layer 115b may not include fine particles. For example, the second optical layer 115b may be made of siloxane, but the example embodiments of the present disclosure are not limited thereto.

For example, the thickness of the first optical layer 115a may be smaller than the thickness of the second optical layer 115b, but the example embodiments of the present disclosure are not limited thereto. Accordingly, when viewed from a planar view, the area where the first optical layer 115a is disposed may include a concave portion that collapses inwardly more than the top surface of the second optical layer 115b.

According to the present disclosure, the second electrode CE2 may be disposed on the first optical layer 115a and the second optical layer 115b. For example, the second electrode CE2 may be electrically connected to the plurality of contact electrodes CCE through the contact hole of the second optical layer 115b. For example, the second electrode CE2 may be disposed on the plurality of micro-LEDs ED. For example, the second electrode CE2 may include a transparent conductive oxide such as indium tin oxide (ITO) or indium zinc oxide (IZO), but the example embodiments of the present disclosure are not limited thereto. For example, the second electrode CE2 may be disposed to be in contact with the cathode electrode 135. For example, the second electrode CE2 may overlap the first optical layer 115a. For example, the second electrode CE2 may cover a flat surface on the outside of the first optical layer 115a.

The second electrode CE2 may continuously extend in a first direction of the substrate 110. Accordingly, the second electrode CE2 may be commonly connected to the plurality of pixels PX arranged in the first direction of the substrate 110. For example, the second electrode CE2 may be commonly connected to the plurality of pixels PX.

According to the present disclosure, the second electrode CE2 may continuously extend on the first optical layer 115a, the second optical layer 115b, and the micro-LED ED. The area where the first optical layer 115a is disposed may include a concave portion that collapses inwardly more than the top surface of the second optical layer 115b. Accordingly, a first portion of the second electrode CE2 disposed on the first optical layer 115a is disposed along the concave portion, and thus may be disposed at a lower position than a second portion of the second electrode CE2 disposed on the second optical layer 115b.

A third optical layer 115c may be disposed on the second electrode CE2. The third optical layer 115c may be disposed to overlap the plurality of micro-LEDs ED and the first optical layer 115a. Since the third optical layer 115c is disposed above the second electrode CE2 and the plurality of micro-LEDs ED, it is possible to improve mura that may occur on some of the plurality of micro-LEDs ED. For example, when the plurality of micro-LEDs ED is transferred onto the substrate 110 of the display apparatus 1000, an area where a spacing between the plurality of micro-LEDs ED is not uniform may occur due to process deviation, etc. When the spacing between the plurality of micro-LEDs ED is not uniform, the light-emitting areas of each of the plurality of micro-LEDs ED may be disposed non-uniformly, and thus, the mura may be visible to a user. Accordingly, since the third optical layer 115c configured to uniformly diffuse light on the upper portion of the plurality of micro-LEDs ED is formed, it is possible to reduce the light emitted from some of the micro-LEDs ED from being visible like mura. Accordingly, since the light emitted from the plurality of micro-LEDs ED is uniformly diffused by the third optical layer 115c and extracted to the outside of the display apparatus 1000, it is possible to improve the brightness uniformity of the display apparatus 1000.

The third optical layer 115c may be made of the organic insulating materials having fine particles dispersed therein, but the example embodiments of the present disclosure are not limited thereto. For example, the third optical layer 115c may be made of siloxane having fine metal particles, such as titanium dioxide (TiO₂) particles, dispersed therein, but the example embodiments of the present disclosure are not limited thereto. For example, the third optical layer 115c may be made of the same material as the first optical layer 115a, but the example embodiments of the present disclosure are not limited thereto. For example, the third optical layer 115c may be a diffusion layer or a top surface diffusion layer, but the example embodiments of the present disclosure are not limited thereto.

According to the present disclosure, the light from the plurality of micro-LEDs ED may be scattered by fine particles dispersed in the third optical layer 115c and emitted to the outside of the display apparatus 1000. The third optical layer 115c may uniformly mix the light emitted from the plurality of micro-LEDs ED, thereby further improving the brightness uniformity of the display apparatus 1000. In addition, the light extraction efficiency of the display apparatus 1000 may be improved by the light scattered from the plurality of fine particles, so the display apparatus 1000 may be driven at low power.

A black matrix BM may be disposed on the second electrode CE2, the first optical layer 115a, the second optical layer 115b, and the third optical layer 115c in the display area AA. For example, the black matrix BM may fill the contact hole of the second optical layer 115b. Since the black matrix BM is configured to cover the display area AA, it is possible to reduce the color mixing of light and external light reflection of the plurality of sub-pixels. For example, since the black matrix BM is also disposed within the contact hole where the second electrode CE2 and the contact electrode CCE are connected, it is possible to suppress light leakage between a plurality of adjacent sub-pixels.

For example, the black matrix BM may be made of an opaque material, but the example embodiments of the present disclosure are not limited thereto. For example, the black matrix BM may be an organic insulating material to which a black pigment or a black dye is added, but the example embodiments of the present disclosure are not limited thereto.

A cover layer 116 may be disposed on a black matrix BM in the display area AA. The cover layer 116 may protect components under the cover layer 116. For example, the cover layer 116 may be made of an organic insulating material, but the example embodiments of the present disclosure are not limited thereto. For example, the cover layer 116 may be made of the photo resist, the polyimide PI, the photo acryl-based material, etc., but the example embodiments of the present disclosure are not limited thereto. For example, the cover layer 116 may be an overcoating layer or an insulating layer, but the example embodiments of the present disclosure are not limited thereto.

The polarizing layer 293 may be disposed on the cover layer 116 via a first adhesive layer 291. The cover member 120 may be disposed on the polarizing layer 293 via a second adhesive layer 295. For example, the first adhesive layer 291 and the second adhesive layer 295 may include the optically clear adhesive (OCA), the optically clear resin (OCR), the pressure sensitive adhesive (PSA), etc., but the example embodiments of the present disclosure are not limited thereto.

According to the present disclosure, the plurality of pad electrodes PE may be disposed on the third insulating layer 113c in the second non-display area NA2. For example, at least some of the plurality of pad electrodes PE may be exposed from the passivation layer 114. For example, the plurality of pad electrodes PE may be electrically connected to the 2-4th connection wiring 122d through the contact hole of the third insulating layer 113c.

An adhesive layer (anisotropic conductive film) ACF may be disposed on the plurality of pad electrodes PE. The adhesive layer ACF may be an adhesive layer in which conductive balls are dispersed in an insulating material, but the example embodiments of the present disclosure are not limited thereto. When heat or pressure is applied to the adhesive layer ACF, the conductive balls may be electrically connected at a portion where the heat or pressure is applied and thus may have conductive properties. The plurality of pad electrodes PE may be attached or bonded to the flexible circuit board (or the flexible film) FCB by disposing the adhesive layer ACF between the plurality of pad electrodes PE and the flexible circuit board (or flexible film) FCB. For example, the adhesive layer ACF may be the anisotropic conductive film ACF, but the example embodiments of the present disclosure are not limited thereto.

The flexible circuit board (or flexible film) FCB may be disposed on the adhesive layer ACF. The flexible circuit board (or flexible film) FCB may be electrically connected to the plurality of pad electrodes PE through the adhesive layer ACF. Therefore, the signal output from the flexible circuit board (or flexible film) FCB and the printed circuit board 160 may be transmitted to the pixel driving circuit PD of the display area AA through the plurality of pad electrodes PE, the 2-4th connection wiring 122d, the 2-3rd connection wiring 122c, the 2-2nd connection wiring 122b, and the 2-1st connection wiring 122a.

In the display apparatus, the pixel driving circuit including the micro driver may be disposed under the micro-LED to drive the micro-LED. In this case, since the micro-LED is disposed above the pixel driving circuit, the flatness of the lower portion of the micro-LED is important in order to normally transfer the micro-LED. That is, the flatness of the upper portion of the pixel driving circuit may affect the transfer rate of the micro-LED. Accordingly, in order to flatten the upper portion of the substrate, the plurality of organic insulating layers may be disposed to surround the pixel driving circuit, and the plurality of organic insulating layers may be disposed at least as thick as the pixel driving circuit.

Meanwhile, in order to ensure that the non-display area is minimally visible to the user, a narrow bezel is implemented in various ways, such as bending a portion of the non-display area toward the rear surface of the display area. That is, the non-display area may include the bending area that is bent toward the rear surface of the display panel. In this case, the plurality of organic insulating layers may be partially removed from the bending area to relieve the bending stress. Accordingly, the number of organic insulating layers disposed in the display area may be greater than the number of organic insulating layers disposed in the bending area, and the height of the organic insulating layer disposed in the display area may be higher than that of the organic insulating layer disposed in the bending area. Accordingly, a step may occur in the display area and the bending area depending on the difference in the number of organic insulating layers disposed. In this case, a phenomenon may occur in which an organic insulating layer in a pre-cured state flows from the display area to the bending area according to the step during the manufacturing process of the display apparatus. Accordingly, a difference in the flatness on the upper portion of the organic insulating layer may occur between an area adjacent to the bending area and an area spaced apart from the bending area at a considerable distance.

In the display apparatus according to the example embodiment of the present disclosure, the substrate 110 and the first buffer layer 111a and the second buffer layer 111b disposed on the substrate 110 may be partially removed in order to mount the pixel driving circuit PD. Accordingly, the substrate 110 may include the groove G disposed in the display area AA, and the pixel driving circuit PD may be disposed in the groove G of the substrate 110. That is, since the pixel driving circuit PD is mounted in the groove G of the substrate 110, the substrate 110 may accommodate the pixel driving circuit PD as deep as the groove G. Accordingly, in the display area AA where the pixel driving circuit PD is disposed, a component for flattening the area where the pixel driving circuit PD is disposed and the area surrounding the area may be omitted or minimized. Accordingly, in the display apparatus 1000 according to the example embodiment of the present disclosure, the thinning of the display apparatus 1000 may be realized. In addition, since an additional process for flattening the area where the pixel driving circuit PD is disposed in the display area AA and the area surrounding the area may be omitted, it is possible to reduce the process cost and time.

In addition, in the display apparatus 1000 according to the example embodiment of the present disclosure, by omitting the component for flattening the display area AA, it is possible to minimize or reduce the step between the display area AA and the bending area BA. Therefore, it is possible to suppress the problem that the organic insulating material composing the layers disposed on the substrate 110 in the display area AA, for example, the protection layer 112, the first insulating layer 113a, the second insulating layer 113b, and the third insulating layer 113c flows into the bending area BA due to the step between the display area AA and the bending area BA. Therefore, it is possible to suppress the phenomenon of the flatness of the display area AA being reduced. That is, in the display apparatus 1000 according to the example embodiment of the present disclosure, the flatness of the lower portion of the micro-LED ED in the display area AA may be secured to improve the transfer rate of the micro-LED ED.

Meanwhile, the adhesive layer may be disposed between the substrate and the pixel driving circuit to fix the pixel driving circuit on the substrate. In this case, when the adhesive layer is disposed on the entire substrate, foreign materials may be attached to an area excluding the area where the pixel driving circuit is disposed during the process. In addition, when the plurality of organic insulating layers is disposed while the foreign materials are attached, the deterioration in the flatness of the upper portion of the plurality of organic insulating layers may be further aggravated. Accordingly, there was the problem that the foreign material removal process had to be additionally performed to suppress the attachment of the foreign materials.

Accordingly, in the display apparatus 1000 according to the example embodiment of the present disclosure, the adhesive pattern Adh for fixing the pixel driving circuit PD on the substrate 110 may be disposed only in the necessary minimum area, for example, the groove G of the substrate 110. Accordingly, unnecessary foreign materials attached onto the adhesive pattern Adh may be minimized or reduced, so it is possible to suppress the phenomenon of the deterioration in flatness due to the foreign materials. In addition, since the process for removing the foreign materials may be omitted, it is possible to reduce the manufacturing process and cost.

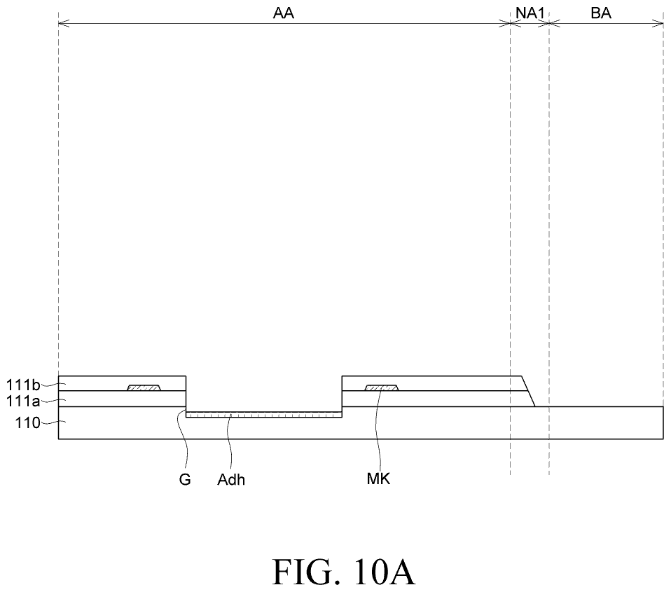

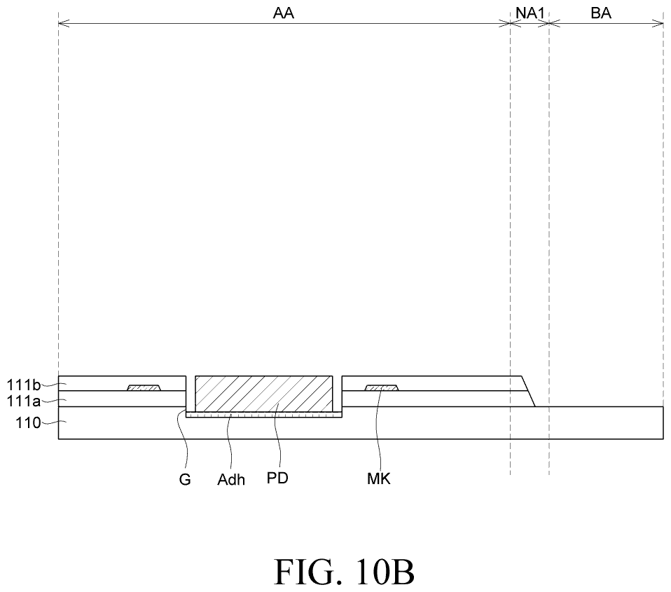

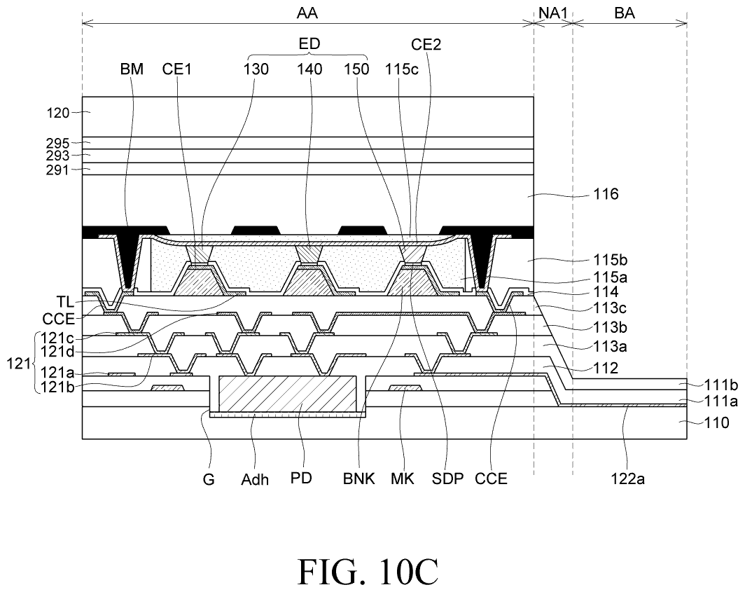

FIGS. 10A to 10C are process diagrams of a method for manufacturing a display apparatus according to an example embodiment of the present disclosure. In FIGS. 10A to 10C, for convenience of description, the illustration of the second non-display area NA2 among the non-display areas NA is omitted.

Referring to FIG. 10A, after the substrate 110, the first buffer layer 111a, and the second buffer layer 111b are sequentially deposited, the substrate 110, the first buffer layer 111a, and the second buffer layer 111b may be partially etched to mount the pixel driving circuit PD. Accordingly, the groove G may be formed in the substrate 110, and the first buffer layer 111a and the second buffer layer 111b may each be spaced apart from each other based on the groove G. That is, the first buffer layer 111a and the second buffer layer 111b may be disposed only in the area excluding the groove G. Meanwhile, since the plurality of pixel driving circuits PD is disposed on the substrate 110, the plurality of grooves G may also be formed. In this case, the width of the groove G may be greater than that of the pixel driving circuit PD so that the pixel driving circuit PD may be mounted.

After the substrate 110, the first buffer layer 111a, and the second buffer layer 111b are partially etched, the adhesive pattern Adh may be disposed on the substrate 110. In this case, the adhesive pattern Adh may be disposed only in the minimum area necessary to adhere and fix the pixel driving circuit PD on the substrate 110 and suppress unnecessary foreign materials from being attached. Accordingly, the adhesive pattern Adh may be disposed only in the groove G of the substrate 110. Therefore, the width of the adhesive pattern Adh may be the same as that of the groove G.

In this case, since the adhesive pattern Adh and the substrate 110 that are in contact with each other are both made of the organic insulating material, it is possible to improve the fixing force between the adhesive pattern Adh and the substrate 110.

Meanwhile, the adhesive pattern Adh is disposed in the groove G of the substrate 110, that is, in a relatively thin area on the substrate 110, and may be disposed at a position relatively lower than the first buffer layer 111a and the second buffer layer 111b disposed in the area on the substrate 110 excluding the groove G, but is not limited thereto.

Next, referring to FIG. 10B, the pixel driving circuit PD may be disposed in the groove G. Specifically, the plurality of pixel driving circuits PD may be disposed in each of the plurality of grooves G. Meanwhile, the pixel driving circuit PD is disposed in the groove G of the substrate 110, that is, in the relatively thin area on the substrate 110, so that the bottom surface of the pixel driving circuit PD may be disposed at a lower position than the bottom surfaces of the first buffer layer 111a and the second buffer layer 111b disposed in the area on the substrate 110 excluding the groove G, but is not limited thereto.

In addition, the heights of the top surfaces of the pixel driving circuit PD and the second buffer layer 111b are illustrated as being disposed on the same plane in the drawings, but are not limited thereto, and the height of the top surface of the pixel driving circuit PD may be designed in various ways depending on the depth of the groove G.

Meanwhile, since the width of the groove G is greater than or equal to that of the pixel driving circuit PD, even if the pixel driving circuit PD is disposed in the groove G, an empty space may be generated inside the groove G. For example, the first buffer layer 111a and the second buffer layer 111b are disposed to surround the area where the groove G is disposed in the display area AA, and thus, the pixel driving circuit PD may be disposed to be spaced apart from the first buffer layer 111a and the second buffer layer 111b. Accordingly, a gap may be generated between the pixel driving circuit PD and the first buffer layer 111a and the second buffer layer 111b, but is not limited thereto.

Next, referring to FIG. 10C, various components including the protection layer 112 may be sequentially disposed on the first buffer layer 111a, the second buffer layer 111b, and the pixel driving circuit PD, so that the manufacturing process of the display apparatus 1000 may be completed.

Specifically, the protection layer 112 may be disposed in the gap between the pixel driving circuit PD and the first buffer layer 111a and the second buffer layer 111b in the groove G. Accordingly, it is possible to remove the air bubbles in the gap between the pixel driving circuit PD and the first buffer layer 111a and the second buffer layer 111b in the groove G. In addition, the protection layer 112 may be disposed to surround the side surface of the pixel driving circuit PD in the groove G to fix and passivate the pixel driving circuit PD. In this case, a portion of the protection layer 112 may be in contact with the adhesive pattern Adh in the groove G, and since both the protection layer 112 and the adhesive pattern Adh are made of the organic insulating material, the pixel driving circuit PD may be fixed more effectively.

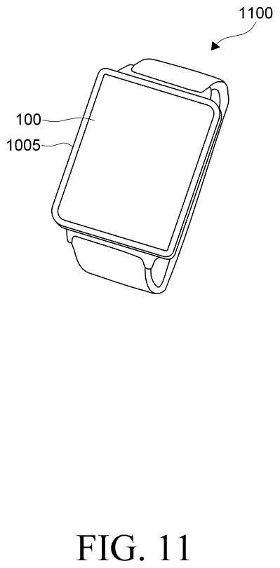

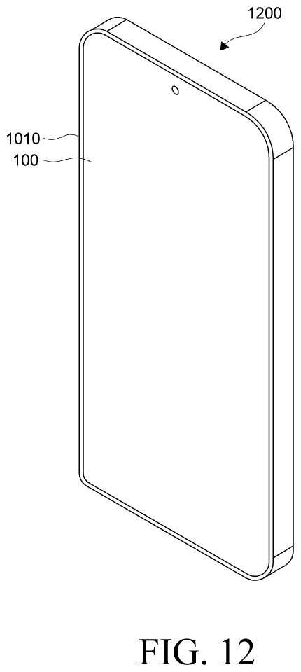

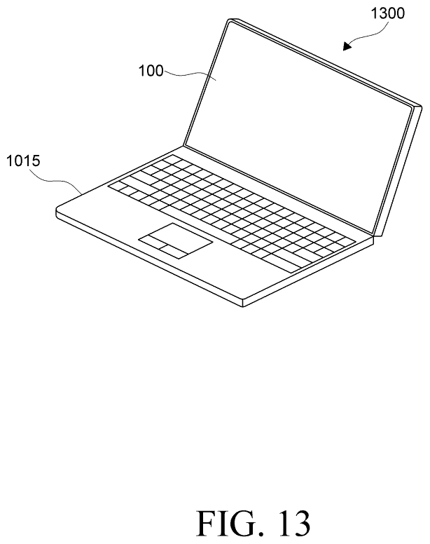

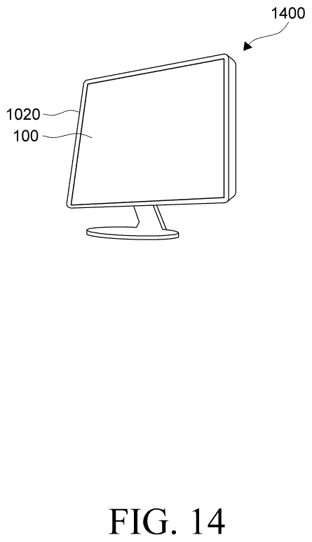

FIGS. 11 to 14 are diagrams illustrating apparatuses to which the display apparatus according to example embodiments of the present disclosure is applied.

Referring to FIGS. 11 to 14, the display apparatus 1000 according to the example embodiments of the present disclosure may be included in various apparatuses or electronic apparatuses. For example, referring to FIGS. 11 to 14, various electronic apparatuses may include a wearable device 1100, a mobile device 1200, a laptop 1300, and a monitor, or TV 1400, but the example embodiments of the present disclosure are not limited thereto.

Each of the wearable device 1100, the mobile device 1200, the laptop 1300, and the monitor or the TV 1400 may include case parts 1005, 1010, 1015, and 1020 and the display panel 100 and the display apparatus 1000 according to the example embodiments of the present disclosure described in FIGS. 1 to 10C.

For example, the display apparatus according to an example embodiment of the present disclosure may be applied to a mobile device, a video phone, a smart watch, a watch phone, a wearable apparatus, a foldable apparatus, a rollable apparatus, a bendable apparatus, a flexible apparatus, a curved apparatus, a sliding apparatus, a variable apparatus, an electronic notebook, an electronic book, a portable multimedia player (PMP), a personal digital assistant (PDA), an MP3 player, a mobile medical apparatus, a desktop PC, a laptop PC, a netbook computer, a workstation, a navigation system, a vehicle display apparatus, a theater display apparatus, a television, a wallpaper apparatus, a signage apparatus, a game console, a laptop, a monitor, a camera, a camcorder, home appliances, etc.

The example embodiments of the present disclosure can also be described as follows:

According to an aspect of the present disclosure, there is provided a display apparatus. The display apparatus includes a substrate, a display area, a non-display area outside the display area, a groove disposed in the display area, an inorganic insulating layer disposed in an area excluding the groove in the display area, a pixel driving circuit disposed in the groove and a plurality of micro-light emitting diodes (micro-LEDs) disposed on the pixel driving circuit and electrically connected to the pixel driving circuit.

A width of the groove may be greater than or equal to a width of the pixel driving circuit.

The display apparatus may further include an adhesive pattern disposed between the pixel driving circuit and the substrate in the groove. A width of the adhesive pattern may be same as a width of the groove.

The adhesive pattern may be spaced apart from the inorganic insulating layer.

The display apparatus may further include a protection layer disposed on the inorganic insulating layer and the pixel driving circuit. A portion of the protection layer may be disposed in the groove.

The pixel driving circuit and the inorganic insulating layer may be spaced apart from each other. The portion of the protection layer may be disposed between the pixel driving circuit and the inorganic insulating layer in the groove.

The portion of the protection layer may be in contact with the adhesive pattern.

The display apparatus may further include a plurality of first connection wirings disposed on the inorganic insulating layer and electrically connected to the pixel driving circuit. Some of the plurality of first connection wirings may be in contact with the inorganic insulating layer.

The non-display area may include a first non-display area, a bending area extending from the first non-display area and a second non-display area extending from the bending area. The display apparatus may further include a plurality of second connection wirings disposed in the display area and the non-display area on the substrate and electrically connected to the pixel driving circuit. Some of the plurality of second connection wirings may be in contact with the inorganic insulating layer in the display area, the first non-display area, and the second non-display area, and may be in contact with the substrate in the bending area.

A height of a bottom surface of the pixel driving circuit may be lower than a height of a bottom surface of the inorganic insulating layer.

The plurality of micro-LEDs may include an anode electrode, a first semiconductor layer disposed on the anode electrode, an active layer disposed on the first semiconductor layer, a second semiconductor layer disposed on the active layer and a cathode electrode disposed on the second semiconductor layer.

The display apparatus may further include a first electrode disposed under the plurality of micro-LEDs to electrically connect the pixel driving circuit and the anode electrode of the plurality of micro-LEDs and a solder pattern disposed between the first electrode and the anode electrode. The first electrode and the anode electrode may be electrically connected through eutectic bonding using the solder pattern.

The display apparatus may further include a plurality of alignment keys disposed on the inorganic insulating layer. A bottom surface of the plurality of alignment keys may be disposed at a higher position than a position of the pixel driving circuit.

According to another aspect of the present disclosure, there is provided a display apparatus. The display apparatus includes a substrate, a plurality of grooves disposed on the substrate, a plurality of pixel driving circuits disposed in each of the plurality of grooves on the substrate, a plurality of inorganic insulating layers disposed to surround the plurality of pixel driving circuits while being spaced apart from the plurality of pixel driving circuits on the substrate, an organic insulating layer on the plurality of inorganic insulating layers and the plurality of pixel driving circuits and a plurality of micro-LEDs disposed on the organic insulating layer and electrically connected to the plurality of pixel driving circuits.

The display apparatus may further include an adhesive pattern disposed between the plurality of pixel driving circuits and the substrate. The adhesive pattern may be disposed only in the plurality of grooves on the substrate.

A height of the adhesive pattern may be lower than a height of the plurality of inorganic insulating layers.

A portion of the organic insulating layer may be disposed to fill a gap between the plurality of pixel driving circuits and the plurality of inorganic insulating layers in the plurality of grooves.

A portion of the organic insulating layer may be disposed to surround side surfaces of the plurality of pixel driving circuits.

The adhesive pattern and the substrate both may be made of an organic insulating material.

A portion of the organic insulating layer may be in contact with the adhesive pattern in a groove of the plurality of grooves.

Although the example embodiments of the present disclosure have been described in detail with reference to the accompanying drawings, the present disclosure is not limited thereto and may be embodied in many different forms without departing from the technical concept of the present disclosure. Therefore, the example embodiments of the present disclosure are provided for illustrative purposes only but not intended to limit the technical concept of the present disclosure. The scope of the technical concept of the present disclosure is not limited thereto. Therefore, it should be understood that the above-described example embodiments are illustrative in all aspects and do not limit the present disclosure. All the technical concepts in the equivalent scope of the present disclosure should be construed as falling within the scope of the present disclosure.

What is claimed is:

1. A display apparatus, comprising:
a substrate;
a display area;
a non-display area outside the display area;
a groove disposed in the display area;
an inorganic insulating layer disposed in an area excluding the groove in the display area;
a pixel driving circuit disposed in the groove; and
a plurality of micro-light emitting diodes (micro-LEDs) disposed on the pixel driving circuit and electrically connected to the pixel driving circuit.

2. The display apparatus of claim 1, wherein a width of the groove is greater than or equal to a width of the pixel driving circuit.

3. The display apparatus of claim 1, further comprising an adhesive pattern disposed between the pixel driving circuit and the substrate in the groove,
wherein a width of the adhesive pattern is same as a width of the groove.

4. The display apparatus of claim 3, wherein the adhesive pattern is spaced apart from the inorganic insulating layer.

5. The display apparatus of claim 3, further comprising a protection layer disposed on the inorganic insulating layer and the pixel driving circuit,
wherein a portion of the protection layer is disposed in the groove.

6. The display apparatus of claim 5, wherein the pixel driving circuit and the inorganic insulating layer are spaced apart from each other, and
the portion of the protection layer is disposed between the pixel driving circuit and the inorganic insulating layer in the groove.

7. The display apparatus of claim 5, wherein the portion of the protection layer is in contact with the adhesive pattern.

8. The display apparatus of claim 1, further comprising:
a plurality of first connection wirings disposed on the inorganic insulating layer and electrically connected to the pixel driving circuit, and
wherein some of the plurality of first connection wirings are in contact with the inorganic insulating layer.

9. The display apparatus of claim 1, wherein the non-display area includes:
a first non-display area;
a bending area extending from the first non-display area; and
a second non-display area extending from the bending area, and
wherein the display apparatus further includes a plurality of second connection wirings disposed in the display area and the non-display area on the substrate and electrically connected to the pixel driving circuit, and
some of the plurality of second connection wirings are in contact with the inorganic insulating layer in the display area, the first non-display area, and the second non-display area, and are in contact with the substrate in the bending area.

10. The display apparatus of claim 1, wherein a height of a bottom surface of the pixel driving circuit is lower than a height of a bottom surface of the inorganic insulating layer.

11. The display apparatus of claim 1, wherein the plurality of micro-LEDs includes:
an anode electrode;
a first semiconductor layer disposed on the anode electrode;
an active layer disposed on the first semiconductor layer;
a second semiconductor layer disposed on the active layer; and
a cathode electrode disposed on the second semiconductor layer.

12. The display apparatus of claim 11, further comprising:
a first electrode disposed under the plurality of micro-LEDs to electrically connect the pixel driving circuit and the anode electrode of the plurality of micro-LEDs; and
a solder pattern disposed between the first electrode and the anode electrode,
wherein the first electrode and the anode electrode are electrically connected through eutectic bonding using the solder pattern.

13. The display apparatus of claim 1, further comprising a plurality of alignment keys disposed on the inorganic insulating layer,
wherein a bottom surface of the plurality of alignment keys is disposed at a higher position than a position of the pixel driving circuit.

14. A display apparatus, comprising:
a substrate;
a plurality of grooves disposed on the substrate;
a plurality of pixel driving circuits disposed in each of the plurality of grooves on the substrate;
a plurality of inorganic insulating layers disposed to surround the plurality of pixel driving circuits while being spaced apart from the plurality of pixel driving circuits on the substrate;
an organic insulating layer on the plurality of inorganic insulating layers and the plurality of pixel driving circuits; and
a plurality of micro-LEDs disposed on the organic insulating layer and electrically connected to the plurality of pixel driving circuits.

15. The display apparatus of claim 14, further comprising an adhesive pattern disposed between the plurality of pixel driving circuits and the substrate,
wherein the adhesive pattern is disposed only in the plurality of grooves on the substrate.

16. The display apparatus of claim 15, wherein a height of the adhesive pattern is lower than a height of the plurality of inorganic insulating layers.

17. The display apparatus of claim 14, wherein a portion of the organic insulating layer is disposed to fill a gap between the plurality of pixel driving circuits and the plurality of inorganic insulating layers in the plurality of grooves.

18. The display apparatus of claim 17, wherein a portion of the organic insulating layer is disposed to surround side surfaces of the plurality of pixel driving circuits.

19. The display apparatus of claim 15, wherein the adhesive pattern and the substrate are both made of an organic insulating material.

20. The display apparatus of claim 15, wherein a portion of the organic insulating layer is in contact with the adhesive pattern in a groove of the plurality of grooves.
